(19) United States
(12) Patent Application Publication
(10) Pub. No.: US 2025/0130457 A1
(43) Pub. Date: Apr. 24, 2025

(54) DISPLAY SUBSTRATE AND PREPARATION METHOD THEREOF, DISPLAY PANEL AND MASK

(71) Applicants: Wuhan BOE Optoelectronics Technology Co., Ltd., Wuhan, Hubei (CN); BOE Technology Group Co., Ltd., Beijing (CN)

(72) Inventors: Yang Wang, Beijing (CN); Haibin Yin, Beijing (CN); Zhiwei Cheng, Beijing (CN); Die Yin, Beijing (CN); Wenlei Xu, Beijing (CN); Xiang Huang, Beijing (CN)

(73) Assignees: Wuhan BOE Optoelectronics Technology Co., Ltd., Wuhan, Hubei (CN); BOE Technology Group Co., Ltd., Beijing (CN)

(21) Appl. No.: 18/687,509

(22) PCT Filed: Feb. 24, 2023
(86) PCT No.: PCT/CN2023/078043

§ 371 Date: Feb. 28, 2024

(51) Int. Cl. G02F 1/1335; G02F 1/1339

(52) U.S. Cl. CPC G02F 1/133516; G02F 1/133512; G02F 1/13398

(57) ABSTRACT

Provided are a display substrate and a preparation method thereof, a display panel and a mask. The display substrate includes an underlayer and an organic structure disposed on the underlayer. The organic structure includes a first surface arranged away from the underlayer; in a direction perpendicular to a plane where the underlayer is located, a difference between a maximum distance between the first surface and the underlayer and a minimum distance between the first surface and the underlayer is less than or equal to 0.06 μm.

### TECHNICAL FIELD

The present application relates to the field of display technology, and in particular to a display substrate and a preparation method thereof, a display panel and a mask.

### BACKGROUND

Mask is a patterning master used in the photolithography field. During the exposure process, the pattern of the photomask is transferred to a corresponding product carrier.

In the related art, a Half-Tone Mask is generally used to simultaneously produce the main photo spacer (PS) and the sub PS to reduce the manufacturing process. The Full-Tone Pattern in the Half-Tone Mask is used to prepare the main PS, and the Half-Tone Pattern in the Half-Tone Mask is used to prepare the sub PS, thereby forming a step difference between the main PS and the sub PS. However, the flatness of the upper surface of the PS in the related art is low, which reduces the supporting effect of the PS.

### SUMMARY

Embodiments of the present disclosure adopt technical solutions described below.

In a first aspect, at least one embodiment of the present disclosure provides a display substrate, including
an underlayer and an organic structure disposed on the underlayer;
the organic structure includes a first surface arranged away from the underlayer;
in a direction perpendicular to a plane where the underlayer is located, a difference between a maximum distance between the first surface and the underlayer and a minimum distance between the first surface and the underlayer is less than or equal to 0.06 μm.

In at least one embodiment of the present disclosure, in the direction perpendicular to the plane where the underlayer is located, a distance from a geometric center of the first surface to the underlayer is greater than or equal to an average value of distances from points on the first surface to the underlayer.

In at least one embodiment of the present disclosure, the organic structure includes a photo spacer, and a surface of the photo spacer facing away from the underlayer is the first surface.

In at least one embodiment of the present disclosure, the organic structure includes color filter patterns, the display substrate includes a display area and a peripheral area surrounding the display area, a dimension, in the direction perpendicular to the plane where the underlayer is located, of a part of the color filter patterns located in the peripheral area is less than or equal to a dimension, in the direction perpendicular to the plane where the underlayer is located, of a part of the color filter patterns located in the display area;
a surface on a side facing away from the underlayer in an area where the color filter pattern located in the peripheral area does not overlap with an adjacent color filter pattern is the first surface.

In at least one embodiment of the present disclosure, a plurality of protrusions and a plurality of dents are provided on the first surface, and each of the dents are located between at least two of the protrusions; a geometric center of the first surface is provided with the protrusion.

In at least one embodiment of the present disclosure, the organic structure includes a first cross section, the first cross section is a cross section in the direction perpendicular to the plane where the underlayer is located, and an intersection line of the first cross section and the first surface is parallel to a side of the first surface;
a number of the protrusions provided at the intersection line of the first surface and the first cross section is an odd number.

In at least one embodiment of the present disclosure, the organic structure includes a first cross section, the first cross section is a cross section in the direction perpendicular to the plane where the underlayer is located, an intersection line of the first cross section and the first surface passes through the geometric center of the first surface;
a number of the protrusions provided at the intersection line of the first surface and the first cross section is an odd number.

In at least one embodiment of the present disclosure, an orthographic projection shape of the first surface on the underlayer is a quadrilateral;
the intersection line of the first surface and the first cross section is parallel to a diagonal of the quadrilateral; or
the intersection line of the first surface and the first cross section is parallel to a side of the quadrilateral.

In at least one embodiment of the present disclosure, the first surface includes a center area and an edge area surrounding the center area, and the geometric center of the first surface is located in the center area;
a maximum distance between a part of the protrusions located in the center area and the underlayer is greater than or equal to a maximum distance between a part of the protrusions located in the edge area and the underlayer.

In at least one embodiment of the present disclosure, a plurality of the protrusions are provided at an outer contour of the first surface, and a maximum distance between a part of the protrusions located on the outer contour of the first surface and the underlayer is less than or equal to a maximum distance between other protrusions and the underlayer.

In at least one embodiment of the present disclosure, the first surface includes a center area and an edge area surrounding the center area, and a geometric center of the first surface is located in the center area;
a curvature radius of a part of protrusions located in the center area is less than or equal to the curvature radius of a part of the protrusions located in the edge area.

In at least one embodiment of the present disclosure, when the organic structure includes the photo spacer, the photo spacer includes a side surface, the side surface being an are surface, and the intersection line of the side surface and the first cross section is an arc.

In at least one embodiment of the present disclosure, a curvature radius of the are gradually decreases in a direction away from the underlayer.

In at least one embodiment of the present disclosure, when the organic structure includes the photo spacer, a distance between vertices of two adjacent protrusions in a direction parallel to the plane where the underlayer is located is equal to ½˜⅙ of a dimension of a planar figure of the photo spacer in a preset direction, wherein the preset direction is a direction pointing to one of the two adjacent protrusions from the other one of the two adjacent protrusions.

In at least one embodiment of the present disclosure, the number of the dents provided at the intersection line of the first surface and the first cross section is an even number, and the number of the protrusions is greater than the number of the dents.

In at least one embodiment of the present disclosure, the number of protrusions provided at the intersection line of the first surface and the first cross section is any one of 3, 5, and 7.

In at least one embodiment of the present disclosure, in the direction perpendicular to the plane where the underlayer is located, a standard deviation of three times the dimension of the organic structure in the direction perpendicular to the plane where the underlayer is located is less than or equal to 0.2 μm.

In a second aspect, an embodiment of the present disclosure provides a display panel including the display substrate as described in the first aspect.

In a third aspect, an embodiment of the present disclosure provides a mask for preparing the display substrate as described in the first aspect, the mask includes a plurality of first slits, each of the first slits is provided with a plurality of first light blocking bars arranged in the same direction and a plurality of second light blocking bars arranged in the same direction, the first light blocking bar intersects with at least one of the second light blocking bars, and a planar figure of patterns in the first slit is a shape in mirror symmetry.

In at least one embodiment of the present disclosure, the number of the first light blocking bars is the same as the number of the second light blocking bars.

In at least one embodiment of the present disclosure, the first light blocking bar is arranged to be perpendicular to the second light blocking bar.

In at least one embodiment of the present disclosure, a minimum spacing between two adjacent first light blocking bars is equal to a minimum spacing between two adjacent second light blocking bars, and minimum spacing between two adjacent first light blocking bars is greater than a width of the first light blocking bar.

In at least one embodiment of the present disclosure, the first light blocking bar and the second light blocking bars have a same structure and same dimensions, any one of the first light blocking bars intersects with all the second light blocking bars, and any one of the second light blocking bars intersects with all the first light blocking bars.

In at least one embodiment of the present disclosure, the first light blocking bars include a first group, a second group and a third group, and the second light blocking bars include a first group, a second group and a third group;
the first group of the first light blocking bars and the second group of the first light blocking bars each include two first light blocking bars, the first group of the second light blocking bars and the second group of the second light blocking bars each include two second light blocking bars; the third group of the first light blocking bars includes one of the first light blocking bars, and the third group of the second light blocking bars includes one of the second light blocking bars;
the first group of the first light blocking bars intersect with the first group of the second light blocking bars to form a first closed ring; the second group of the first light blocking bars intersect with the second group of the second light blocking bars to form a second closed ring; the second closed ring is located inside the first closed ring; the third group of the first light blocking bars intersects with the third group of the second light blocking bars, and the third group of the first light blocking bars and the third group of the second light blocking bars intersect with the first closed ring and the second closed ring respectively, a geometric center of the mask is located at an intersection of the third group of the first light blocking bars and the third group of the second light blocking bars.

In at least one embodiment of the present disclosure, the minimum spacing between two adjacent first light blocking bars ranges from 2.5 μm to 14 μm, and the width of the first light blocking bar ranges from 1 μm to 4 μm.

In a fourth aspect, an embodiment of the present disclosure provides a preparation method of a display substrate, the method includes:
providing an underlayer;
forming a photo spacer material film; and
obtaining a photo spacer by using the mask according to claim 23 to pattern the photo spacer material film; wherein the photo spacer comprises a first surface that is arranged away from the underlayer and is provided with a plurality of protrusions and a plurality of dents, and the dents are located between at least two protrusions; wherein a geometric center of the first surface is provided with the protrusion; in a direction perpendicular to a plane where the underlayer is located, a difference between a maximum distance between the first surface and the underlayer and a minimum distance between the first surface and the underlayer is less than or equal to 0.06 μm.

In at least one embodiment of the present disclosure, the obtaining a photo spacer by using the mask described above to pattern the photo spacer material film includes:
determining a preset height and preset planar dimensions of the photo spacer;
determining two parameters among three parameters of a number of the first light blocking bars in the mask, a width of the first light blocking bars, and a minimum spacing between two adjacent first light blocking bars; wherein the number of the first light blocking bars is the same as the number of the second light blocking bars, the width of the first light blocking bars is the same as the width of the second light blocking bars, and the minimum spacing between two adjacent first light blocking bars is the same as the minimum spacing between two adjacent second light blocking bars;
obtaining a preset relationship between an unknown parameter, among the three parameters of the number of the first light blocking bars, the width of the first light blocking bars, and the minimum spacing between two adjacent first light blocking bars, and dimensional parameters of the photo spacer;
determining the unknown parameter of the mask according to the dimensional parameters of the photo spacer and the preset relationship; and
determining specifications of the mask according to the three parameters of the mask, and then obtaining the photo spacer by using the mask to pattern the photo spacer material film.

In at least one embodiment of the present disclosure, the determining two parameters among three parameters of a number of the first light blocking bars in the mask, a width of the first light blocking bars, and a minimum spacing between two adjacent first light blocking bars includes:
determining the number of the first light blocking bars in the mask and the width of the first light blocking bars.

In at least one embodiment of the present disclosure, the obtaining a preset relationship between an unknown parameter, among the three parameters of the number of the first light blocking bars, the width of the first light blocking bars, and the minimum spacing between two adjacent first light blocking bars, and dimensional parameters of the photo spacer includes:
obtaining the preset relationship between the minimum spacing between two adjacent first light blocking bars and the dimensional parameters of the photo spacer; wherein the dimensional parameters include the height and planar dimensions.

In at least one embodiment of the present disclosure, the height of the photo spacer decreases as the minimum spacing between two adjacent first light blocking bars increases, and the planar dimensions of the photo spacer increase as the minimum spacing between the two adjacent first light blocking bars increases; the minimum spacing between two adjacent first light blocking bars is the same as the minimum spacing between two adjacent second light blocking bars.

In at least one embodiment of the present disclosure, the planar dimensions of the photo spacer includes a dimension in a first direction and a dimension in a second direction, and the first direction is perpendicular to the second direction, the dimension in the first direction increases as the minimum spacing between two adjacent first light blocking bars increases, the dimension in the second direction increases as the minimum spacing between two adjacent first light blocking bars increases, the second direction is consistent with an extension direction of the first light blocking bar, and the first direction is consistent with the extension direction of the second light blocking bar.

The above explanation is merely an overview of the technical solutions of the present disclosure. In order to know about the technical means of the present disclosure more clearly so that the solutions may be implemented according to the contents of the specification, and in order to make the above and other objects, features and advantages of the present disclosure more apparent and understandable, specific implementations of the present disclosure are set forth below.

### BRIEF DESCRIPTION OF THE DRAWINGS

In order to illustrate technical solutions of the embodiments of the present disclosure or the related art more clearly, the accompanying drawings used in the illustration of the embodiments or the related art will be briefly introduced. Apparently, the accompanying drawings in the following explanation illustrate merely some embodiments of the present disclosure, and those skilled in the art may obtain other accompanying drawings based on these accompanying drawings without paying any creative effort.

FIG. 1 is a cross-sectional view of a photo spacer in the related art provided by an embodiment of the present disclosure;

FIG. 2 is a schematic structural diagram of a display substrate provided by an embodiment of the present disclosure;

FIG. 3 is a schematic structural diagram of another display substrate provided by an embodiment of the present disclosure;

Graph (1) in FIG. 4 is a top structural view of a photo spacer provided by an embodiment of the present disclosure; Graph (2) in FIG. 4 is a cross-sectional view along A1A2 direction in graph (1) of FIG. 4; Graph (3) in FIG. 4 is a partial enlarged view of Graph (2) in FIG. 4;

Graph (1) in FIG. 5 is a top structural view of another photo spacer provided by an embodiment of the present disclosure; Graph (2) in FIG. 5 is a cross-sectional view along A3A4 direction in graph (1) of FIG. 4; Graph (3) in FIG. 5 is a partial enlarged view of Graph (2) in FIG. 5;

FIG. 6 to FIG. 11 are cross-sectional views of six other photo spacers provided by embodiments of the present disclosure;

FIG. 12 to FIG. 15 are schematic structural diagrams illustrating four types of masks provided by embodiments of the present disclosure;

FIG. 16 is a flow chart of a preparation method of a photo spacer provided by an embodiment of the present disclosure;

FIG. 17 is a flow chart of another preparation method of a photo spacer provided by an embodiment of the present disclosure;

FIG. 18 to FIG. 19 are schematic structural diagrams illustrating another two masks provided by embodiments of the present disclosure;

FIG. 20A is a simulation curve illustrating an influence of changes in a width of a light blocking bar in three different masks provided by embodiments of the present disclosure on a height of the photo spacer;

FIG. 20B is a simulation curve illustrating an influence of changes in a width of a light blocking bar in three different masks provided by embodiments of the present disclosure on a dimension of the photo spacer in a first direction;

FIG. 20C is a simulation curve illustrating an influence of changes in a width of a light blocking bar in three different masks provided by embodiments of the present disclosure on a dimension of the photo spacer in a second direction;

FIG. 21A is a simulation curve illustrating an influence of changes in a spacing between light blocking bars in three different masks provided by embodiments of the present disclosure on a height of the photo spacer;

FIG. 21B is a simulation curve illustrating an influence of changes in a spacing between light blocking bars in three different masks provided by embodiments of the present disclosure on a dimension of the photo spacer in a first direction;

FIG. 21C is a simulation curve illustrating an influence of changes in a spacing between light blocking bars in three different masks provided by embodiments of the present disclosure on a dimension of the photo spacer in a second direction;

FIG. 22 illustrates a top view and a three-dimensional perspective view of photo spacers prepared through three different masks provided in embodiments of the present disclosure, where three different masks are respectively used for Case1, Case2 and Case3;

FIG. 23A is an actual measured curve illustrating an influence of changes in a width of a light blocking bar in three different masks provided by embodiments of the present disclosure on a height of the photo spacer;

FIG. 23B is an actual measured curve illustrating an influence of changes in a width of a light blocking bar in three different masks provided by embodiments of the present disclosure on a dimension of the photo spacer in a first direction:

FIG. 23C is an actual measured curve illustrating an influence of changes in a width of a light blocking bar in three different masks provided by embodiments of the present disclosure on a dimension of the photo spacer in a second direction;

FIG. 24A is an actual measured curve illustrating an influence of changes in a spacing between light blocking bars in three different masks provided by embodiments of the present disclosure on a height of the photo spacer:

FIG. 24B is an actual measured curve illustrating an influence of changes in a spacing between light blocking bars in three different masks provided by embodiments of the present disclosure on a dimension of the photo spacer in a first direction;

FIG. 24C is an actual measured curve illustrating an influence of changes in a spacing between light blocking bars in three different masks provided by embodiments of the present disclosure on a dimension of the photo spacer in a second direction;

FIG. 25A is a curve illustrating an influence of a number of light blocking bars, a spacing between light blocking bars, and a width of light blocking bar in the same mask provided by an embodiment of the present disclosure on a height of a photo spacer;

FIG. 25B is a curve illustrating an influence of a number of light blocking bars, a spacing between light blocking bars, and a width of light blocking bar in a first direction in the same mask provided by an embodiment of the present disclosure on a dimension of a photo spacer;

FIG. 25C is a curve illustrating an influence of a number of light blocking bars, a spacing between light blocking bars, and a width of light blocking bar in a second direction in the same mask provided by an embodiment of the present disclosure on a dimension of a photo spacer:

FIG. 26A is a curve illustrating an influence of a width of a light blocking bar in the same mask provided by an embodiment of the present disclosure on a height of a photo spacer;

FIG. 26B is a curve illustrating an influence of a width of a light blocking bar in the same mask provided by an embodiment of the present disclosure on a dimension of a photo spacer in a first direction; and

FIG. 26C is a curve illustrating an influence of a width of a light blocking bar in the same mask provided by an embodiment of the present disclosure on a dimension of a photo spacer in a second direction;

### DETAILED DESCRIPTION

A clear and thorough illustrating for technical solutions in the embodiments of the present disclosure will be given below in conjunction with the accompanying drawings in the embodiments of the present disclosure. Apparently, the described embodiments are merely a part of embodiments of the present disclosure, not all the embodiments. All other embodiments obtained, based on the embodiments in the present disclosure, by those skilled in the art without paying creative effort fall within the protection scope of the present disclosure.

Unless it is otherwise defined in the context, the term “comprising/including” throughout the specification and claims is interpreted in an open and inclusive sense, that is, “including, but not limited to”. In the explanation of the specification, the terms “an embodiment”. “some embodiments”, “an exemplary embodiment”, “an example”. “specific examples” or “some examples” are intended to indicate that specific features, structures, materials or characteristics related to the embodiment or example are included in at least one embodiment or example of the present disclosure. Schematic representations of the above terms do not necessarily refer to the same embodiment or example. Furthermore, the particular features, structures, materials or characteristics described may be included in any suitable manner in any one or more embodiments or examples.

In the embodiments of the present disclosure, wordings such as “first” and “second” are used to distinguish the same or similar items with basically the same function and effect, and are only used for clearly describing the technical solutions of the embodiments of the present disclosure, and cannot be understood as indicating or implying relative importance or implicitly indicating the number of indicated technical features.

Features such as “parallel”, “perpendicular” and “identical” used in the embodiments of the present disclosure include features in a strict meaning of “parallel”, “perpendicular”, “identical”, as well as conditions with a certain error such as “approximately parallel”, “approximately perpendicular”, “substantially the same”, considering the error in the measurement and associated with the measurement of the particular quantity (e.g., limitations of a measurement system), meaning that it is within a deviation range of a particular value acceptable for those skilled in the art. For example, “approximately” may mean being within one or more standard deviations, or within 10% or 5% of a stated value. “At least one” means one or more, and “plurality” means at least two.

“Being In a same layer” as mentioned in the embodiments of the present disclosure refers to a relationship between multiple film layers formed by the same material through the same step (for example, one patterning process). “Being is the same layer” herein does not always mean that the thicknesses of multiple film layers are the same or that the heights of the multiple film layers in the cross-sectional view are the same.

The polygons in the specification are not in the strict sense, and may be approximate triangles, parallelograms, trapezoids, pentagons or hexagons, etc. There may be some small deformations caused by fluctuations or tolerances in the manufacturing process.

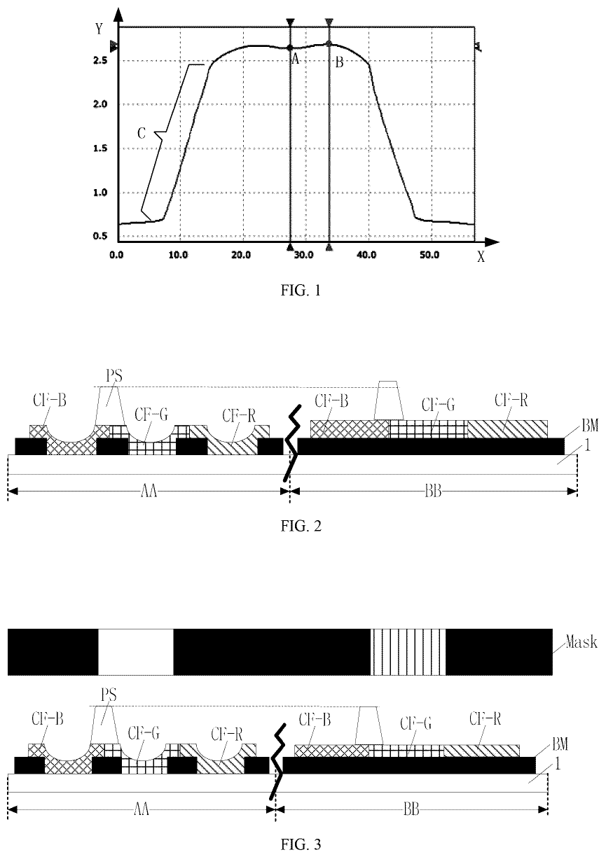

With the continuous development of display technology, people's pursuit of the display quality and reliability of display products is also getting higher and higher. In the related art, there is often a large and deep dent at the center of the upper surface of the sub photo spacer (Sub PS). When the display product is subjected to an external force and the main photo spacer (Main PS) is compressed, the sub photo spacer needs to play an auxiliary supporting role to prevent the photo spacer from being damaged. However, as shown in FIG. 1, since there is a large and deep dent at the center of the upper surface of the Sub PS, the contact area between the upper surface of the Sub PS and the upper substrate of the display product is insufficient, reducing the supporting effect of the Sub PS. Accordingly, both the main PS and the Sub PS may be damaged in severe cases, resulting in abnormal display of the display product. It should be noted that the outline in FIG. 1 is a cross section of the Sub photo spacer in a direction perpendicular to a plane where the underlayer of the display substrate is located, and the cross section passes through the geometric center of the upper surface of the Sub photo spacer. The geometric center of the upper surface of the Sub photo spacer is located in an area where the dent is located. For example, the lowest point A of the dent may coincide with the geometric center, and the highest point B of the upper surface of the Sub photo spacer may be located at the edge of the dent.

In view of the structure and the supporting effect of the current Sub photo spacer, it is urgent to provide a new structure of the photo spacer to improve the supporting effect of the photo spacer and the service life thereof in a display product.

At least one embodiment of the present disclosure provides a display substrate, including: an underlayer 1 and an organic structure disposed on the underlayer 1;
the organic structure includes a first surface M1 that is disposed facing away from the underlayer 1;
in a direction perpendicular to a plane of the underlayer 1, a difference between the maximum distance between the first surface M1 and the underlayer 1 and the minimum distance between the first surface M1 and the underlayer 1 is less than or equal to 0.06 μm.

In an exemplary embodiment, the organic structure may include a photo spacer. Alternatively, the organic structure may include a color filter pattern.

The type of the photo spacer is not limited herein. For example, the photo spacer may be a main photo spacer (Main PS). As another example, the photo spacer may be a Sub photo spacer (Sub PS).

The specific color of the color filter pattern is not limited herein. For example, the color filter pattern may include at least one of a red color filter pattern, a green color filter pattern, and a blue color filter pattern.

Exemplarily, the organic structure may include a color filter pattern located in the display area AA, and/or the organic structure may include a color filter pattern located in the peripheral area BB, where the peripheral area BB is arranged around the display area AA.

For example, the organic structure includes a color filter pattern located in the display area AA.

As another example, the above organic structure includes a color filter pattern located in the peripheral area BB.

As still another example, the organic structure includes both a color filter pattern located in the display area AA and a color filter pattern located in the peripheral area BB.

The material of the underlayer 1 is not limited herein. For example, the material of the underlayer 1 may be a rigid material such as glass; or the material of the underlayer 1 may be a flexible material such as polyimide.

The preparation process of the organic structure is not limited herein. For example, the organic structure may be prepared by using a half-tone mask; or, the organic structure may be prepared by using a gray tone mask.

The first surface M1 refers to a surface of the organic structure that is far away from the underlayer 1 of the display substrate.

The shape of the planar figure of the first surface M1 is not limited herein. The planar figure of the first surface M1 refers to the figure of the orthographic projection of the first surface M1 on the underlayer 1.

Exemplarily, the shape of the planar figure of the first surface M1 may include polygons, arcs, and a combination of polygons and arcs.

For example, polygons may include squares, rectangles, rhombuses, and pentagons; arcs may include circles and ellipses. The polygons in the specification are not strictly defined, that is, the squares, rectangles, rhombuses, and pentagons may all have some small deformations caused by tolerances.

The above deformations may include a rounded corner deformation. For example, a square may be deformed as a rounded square. As another example, a rectangle may be deformed as a rounded rectangle. Similar deformations may also exist for other figures, which will not be described herein.

In a direction perpendicular to a plane of the underlayer 1, a difference between the maximum distance between the first surface M1 and the underlayer 1 and the minimum distance between the first surface M1 and the substrate 1 is less than or equal to 0.06 μm.

Exemplarily, in a direction perpendicular to a plane of the underlayer 1, the difference between the maximum distance between the first surface M1 and the underlayer 1 and the minimum distance between the first surface M1 and the substrate 1 may be 0.015 μm, 0.020 μm, 0.023 μm, 0.025 μm, 0.030 μm, 0.033 μm, 0.035 μm, 0.040 μm, 0.041 μm, 0.045 μm, 0.050 μm, 0.055 μm.

Due to the difference between the design of the organic structure and the preparation process, the first surface M1 is not an ideal plane, and the distances from various positions on the first surface M1 to the underlayer 1 are not exactly the same. In the present disclosure, the difference between the maximum distance between the first surface M1 of the organic structure and the underlayer 1 and the minimum distance between the first surface M1 and the underlayer 1 is less than or equal to 0.06 μm, that is, the first surface M1 of the organic structure has relatively high flatness. Therefore, when a display panel prepared from the display substrate is pressed, the organic structure can play a better supporting role and the quality of the display panel is improved.

In at least one embodiment of the present disclosure, in the direction perpendicular to the plane of the underlayer 1, the distance from the geometric center of the first surface M1 to the underlayer 1 is greater than or equal to an average value of the distances from various points on the first surface M1 to the underlayer 1.

Compared with that a large and deep dent generally exists at the center of the upper surface of the photo spacer in the related art, in at least one embodiment of the present disclosure, in the direction perpendicular to the plane of the underlayer 1, the distance from the geometric center of the first surface M1 to the underlayer 1 is greater than or equal to the average value of the distances from various points on the first surface M1 to the underlayer 1, so that there is no dent at the center of the first surface M1 of the organic structure. Therefore, the flatness near the center position of the first surface M1 of the organic structure can be improved, and the quality of the organic structure is improved.

In at least one embodiment of the present disclosure, the organic structure includes a photo spacer (PS), and the surface of the photo spacer (PS) facing away from the underlayer 1 is the first surface M1.

For example, the photo spacer may be a main photo spacer (Main PS). As another example, the photo spacer may be a Sub photo spacer (Sub PS). As an example, the display substrate provided by embodiments of the present disclosure is explained by using the Sub photo spacer (PS) as the PS.

In at least one embodiment of the present disclosure, the organic structure includes a color filter pattern (for example CF-R, CF-G, CF-B). The display substrate includes a display area AA and a peripheral area BB surrounding the display area AA. Along the direction perpendicular to the plane of the underlayer 1, the dimension of a part of the color filter patterns located in the peripheral area BB is less than or equal to the dimension of a part of the color filter patterns located in the display area AA. The surface on a side facing away from the underlayer 1 in the area where the color filter pattern located in the peripheral area BB does not overlap with the adjacent color filter pattern is the first surface M1.

Exemplarily, along the direction perpendicular to the plane of the underlayer 1, the dimension of the part of the color filter pattern located in the peripheral area BB is smaller than the dimension of the part of the color filter pattern located in the display area AA, that is, the thickness of the part of the color filter pattern located in the peripheral area BB is smaller than the thickness of the part of the color filter pattern located in the display area AA.

In an exemplary embodiment, the color filter pattern may include at least one of a red color filter pattern, a green color filter pattern, and a blue color filter pattern.

For example, the color film pattern may include a red color film pattern, a green color film pattern, and a blue color film pattern, and the red color film pattern, the green color film pattern, and the blue color film pattern are arranged in sequence.

The part of the color filter pattern located in the peripheral area BB can be used together with a photo spacer and a black matrix to block the expansion of the alignment liquid. Specifically, when being coated, the alignment liquid covers the color film pattern in the display area AA. However, due to the fluidity of the alignment liquid, the alignment liquid expands outward to the peripheral area BB and even spreads to the sealant, which will seriously reduce the adhesion performance of the sealant. In order to prevent the alignment liquid from expanding outward, a black matrix, a color filter pattern and a photo spacer are provided in a local area of the peripheral area BB close to the display area AA. The black matrix, the color filter pattern and the photo spacer are stacked to block the alignment liquid to flow outward.

Exemplarily, as shown in FIG. 2, the peripheral area BB is provided with a black matrix BM, a color filter pattern (such as CF-R, CF-G, CF-B) and a photo spacer PS located on the underlayer 1. When the thickness of the black matrix in the peripheral area BB, the thickness of the color filter pattern in the peripheral area BB and the thickness of the photo spacer in the peripheral area BB are the same as the thickness of the black matrix in the display area AA, the thickness of the color filter pattern in the display area AA and the thickness of the photo spacer in the display area AA respectively, since the color filter pattern in the peripheral area BB is disposed on the black matrix BM and the color filter pattern in the display area AA is disposed between the black matrix BM, the distance between the upper surface of the photo spacer located in the peripheral area BB and the underlayer 1 is greater than the distance between the upper surface of the photo spacer located in the display area AA and the underlayer 1, which may easily cause the edge of the display panel to turn yellow or a problem of light leakage at edges.

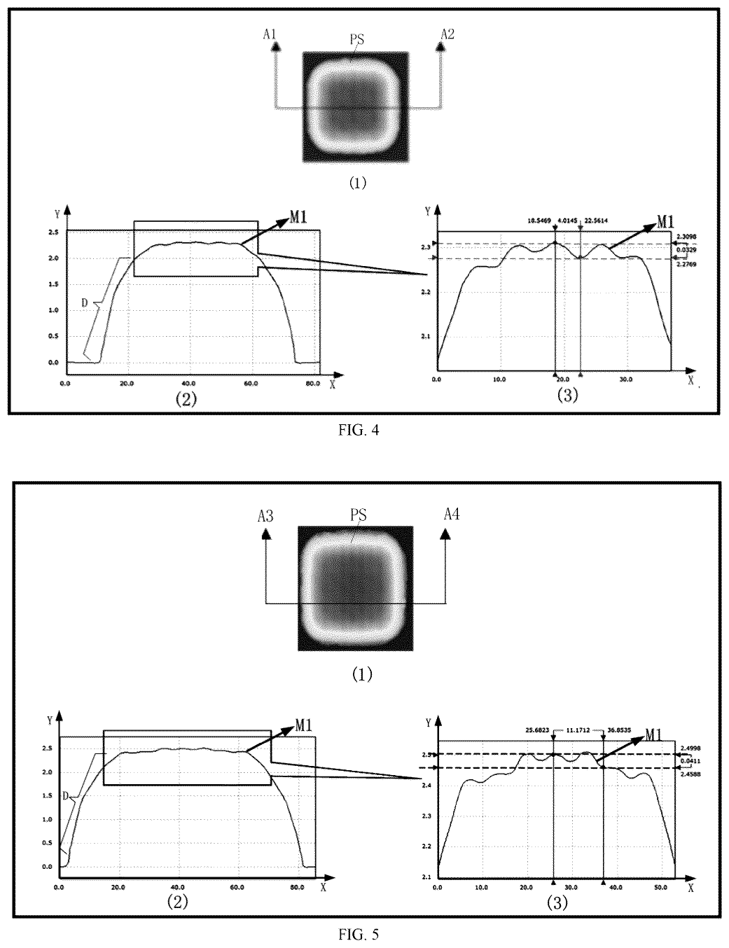

In order to make the distance between the upper surface of the photo spacer located in the peripheral area BB and the underlayer 1 equal to the distance between the upper surface of the photo spacer located in the display area AA and the underlayer 1, as shown in FIG. 3, along the direction perpendicular to the plane where the underlayer 1 is located, the dimension of the part of the color filter pattern located in the peripheral area BB is set to be less than or equal to the dimension of the part of the color filter pattern located in the display area AA. In this way, the quality of the display panel prepared from the display substrate can be ensured.

FIG. 3 is a schematic structural diagram illustrating a mask used to prepare a display substrate. The part of the color filter pattern located in the peripheral area BB can be prepared using the gray tone pattern in the gray tone mask (GTM), and the part of the color filter pattern located in the display area AA can be prepared using a full tone pattern in the GTM.

Of course, the part of the color filter pattern located in the peripheral area BB can be prepared using the half-tone pattern in the half-tone mask (HTM), and the part of the color filter pattern located in the display area AA can be prepared using the full tone pattern in the HTM.

It should be noted that when the organic structure includes a color filter pattern located in the peripheral area BB, due to normal fluctuations in the accuracy of the preparation process and the alignment accuracy of equipment, two adjacent color filter patterns may overlap. For example, when a blue color filter pattern is formed first and then a green color film pattern adjacent to the blue color film pattern is formed, the green color film pattern may partially cover the blue color film pattern. The first surface M1 mentioned in the embodiments of the present disclosure refers to a surface facing away from the underlayer 1 in an area not overlapping with the adjacent color filter pattern. By way of example, two adjacent color filter patterns do not overlap in the drawings provided in the embodiments of the present disclosure.

In at least one embodiment of the present disclosure, a plurality of protrusions and a plurality of dents are provided on the first surface M1, and the dents are located between at least two protrusions; a protrusion is provided at the geometric center of the first surface M1.

Exemplarily, in the case where the organic structure includes a photo spacer, as shown in graph (2) of FIG. 4 and graph (3) of FIG. 4, a plurality of protrusions and a plurality of dents are provided on the first surface M1 of the photo spacer, and a protrusion is provided at the geometric center position of the first surface M1. Graph (2) in FIG. 4 is a cross-sectional view of graph (1) in FIG. 4 along the A1A2 direction, which is a cross-sectional view of the photo spacer along the direction perpendicular to the plane of the underlayer 1 and passing through the geometric center of the first surface M1, graph (3) in FIG. 4 is a partial enlarged view of the marked box area in graph (2) in FIG. 4.

Exemplarily, in the case where the organic structure includes a color filter pattern located in the peripheral area BB, a plurality of protrusions and a plurality of dents are provided on the first surface M1 of the color filter pattern, and a protrusion is provided at the geometric center of the first surface M1, the first surface M1 of the color filter pattern is the surface on a side facing away from the underlayer 1 in the area not overlapping with the adjacent color filter pattern.

In at least one embodiment of the present disclosure, the structure of the first surface M1 of the color filter pattern located in the display area AA may be set to be the same as the structure of the first surface M1 of the color filter pattern located in the peripheral area BB.

The dimension of the above-mentioned protrusions and dents is not limited herein.

Exemplarily, for the protrusion on the first surface M1 of the photo spacer, a dimension range thereof in a direction parallel to the plane of the underlayer 1 may be 5 μm to 20 μm, and a dimension range thereof in the direction perpendicular to the plane of the underlayer 1 may be 0.02 μm to 0.06 μm; for the dent on the first surface M1 of the photo spacer, a dimension range thereof in the direction parallel to the plane of the underlayer 1 and a dimension range thereof in the direction perpendicular to the plane of the underlayer 1 is similar to the dimension ranges of the protrusion, which will not be repeated herein;

For example, on the first surface M1 of the photo spacer, the dimension of the protrusion in the direction parallel to the plane of the underlayer 1 may be 12 μm, 11.5 m, 11.2 μm, 11.0 μm, 10.8 μm, 10.3 μm, 10 μm, 9.8 μm, 9.5 μm, 9.2 μm, 9.0 μm, 8.8 μm, 8.5 μm, 8.3 μm, 8.0 μm, 7.5 μm, 7.0 μm, 6.8 μm, 6.5 μm, 6.0 μm, 5.8 μm, 5.5 μm.

For another example, on the first surface M1 of the photo spacer, the dimension of the protrusion in the direction perpendicular to the plane of the underlayer 1 may be 0.03 μm, 0.035 μm, 0.038 μm, 0.040 μm, 0.043 μm, 0.045 μm, 0.048 μm, 0.050 μm, 0.052 μm, 0.055 μm, 0.058 μm.

Exemplarily, for the protrusion on the first surface M1 of the color filter pattern located in the peripheral area BB, the dimension range thereof in the direction parallel to the plane of the underlayer 1 may be 5 μm to 30 μm, and the dimension range thereof in the direction perpendicular to the plane of the underlayer 1 may be 0.005 μm to 0.06 μm;

For example, on the first surface M1 of the color filter pattern located in the peripheral area BB, the dimension of the protrusion in the direction parallel to the plane of the underlayer 1 may be 26 μm, 25 μm, 24 μm, 23 μm, 22 μm, 20 μm, 19 μm, 18 μm, 17.6 μm, 17 μm, 16.5 μm, 16 μm, 15.5 μm, 15 μm, 14.5 μm, 14 μm, 13.5 μm, 13 μm, 12 μm, 11.5 μm, 11.2 μm, 11.0 μm, 10.8 μm, 10.3 μm, 10 μm, 9.8 μm, 9.5 μm, 9.2 μm, 9.0 μm, 8.8 μm, 8.5 μm, 8.3 μm, 8.0 μm, 7.5 μm, 7.0 μm, 6.8 μm, 6.5 μm, 6.0 μm, 5.8 μm, 5.5 μm.

For another example, on the first surface M1 of the color filter pattern located in the peripheral area BB, the dimension of the protrusion in the direction perpendicular to the plane of the underlayer 1 may be 0.006 μm, 0.007 μm, 0.008 μm, 0.009 μm, 0.01 μm, 0.02 μm, 0.03 μm, 0.035 μm, 0.038 μm, 0.040 μm, 0.043 μm, 0.045 μm, 0.048 μm, 0.050 μm, 0.052 μm, 0.055 μm, 0.058 μm.

It should be noted that the above exemplary dimensions are all average values, and in actual applications, the actual dimension of each protrusion may fluctuate around the average value.

In at least one embodiment of the present disclosure, the number of protrusions and dents on the first surface M1 is not limited.

In the photo spacer shown in graph (3) of FIG. 4 provided by the embodiment of the present disclosure, since a protrusion is provided at the geometric center of the first surface M1, compared with the structure of the photo spacer provided in the related art and shown in FIG. 1, a larger supporting contact area can be provided, so that the supporting function of the photo spacer is improved and the probability that the photo spacer will be compressed and deformed, unable to recover or be crushed, is reduced. Therefore, the quality of the display substrate is improved.

In at least one embodiment of the present disclosure, the organic structure includes a first cross section that is a cross section in the direction perpendicular to the plane of the underlayer 1, and the intersection line of the first cross section and the first surface M1 is parallel to sides of the first surface M1.

The number of protrusions provided at the intersection line of the first surface M1 and the first cross section is an odd number.

For example, taking an organic structure as a photo spacer for illustration, as shown in graph (1) in FIG. 4 and graph (1) in FIG. 5, the intersection line of the first cross section (the positions marked A1A2 and A3A4 are the intersection of the first cross section and the first surface M1) and the first surface M1 is parallel to the side of the first surface M1. The structures shown in graph (1) of FIG. 4 and graph (1) of FIG. 5 are both the first surface M1 of the photo spacer. Graph (2) in FIG. 5 is a cross-sectional view along the A3A4 direction in graph (1) in FIG. 5.

Exemplarily, as shown in graph (3) of FIG. 4, the first cross section is a cross section in the direction perpendicular to the plane of the underlayer 1, and the intersection line of the first cross section and the first surface M1 is parallel to the side of the first surface M1; five protrusions are provided at the intersection line of the first surface M1 and the first cross section.

Exemplarily, as shown in graph (3) of FIG. 5, the first cross section is a cross section in the direction perpendicular to the plane of the underlayer 1, and the intersection line of the first cross section and the first surface M1 is parallel to the side of the first surface M1; seven protrusions are provided at the intersection line of the first surface M1 and the first cross section.

For the color filter pattern located in the peripheral area BB, the intersection line of the first cross section and the first surface M1 is parallel to the side of the first surface M1, and the number of protrusions provided at the intersection line of the first surface M1 and the first cross section is an odd number.

For example, for the color filter pattern located in the peripheral area BB, the number of protrusions provided at the intersection line of the first surface M1 and the first cross section may be 3, 5, 7 or 9.

In at least one embodiment of the present disclosure, the organic structure includes a first cross section that is a cross section along the direction perpendicular to the plane of the underlayer 1, and the intersection line of the first cross section and the first surface M1 passes through the geometric center of the first surface M1; and the number of protrusions provided at the intersection line of the first surface M1 and the first cross section is an odd number.

Exemplarily, when the intersection line of the first cross section and the first surface M1 passes through the geometric center of the first surface M1, the number of protrusions provided at the intersection line of the first surface M1 and the first cross section is an odd number. For example, regardless of a photo spacer or a color filter pattern, and the number of protrusions provided at the intersection line of the first surface M1 and the first cross section may be 3, 5, 7 or 9.

Exemplarily, regardless of the photo spacer or the color filter pattern, the plurality of protrusions provided at the intersection line of the first surface M1 and the first cross section are distributed in a mirror symmetry.

In at least one embodiment of the present disclosure, an orthographic projection of the first surface M1 on the underlayer 1 is a quadrilateral; the intersection line of the first surface M1 and the first cross section is parallel to the diagonal of the quadrilateral.

Alternatively, the intersection line of the first surface M1 and the first cross section is parallel to the side of the quadrilateral.

It should be noted that the above-mentioned quadrilateral is not necessarily a standard quadrilateral. It may also be a slight variant based on the standard quadrilateral, including but not limited to a standard quadrilateral and a rounded quadrilateral.

When the organic structure includes a photo spacer or a color filter structure, the first cross section passing through the geometric center of the first surface M1 may include two situations.

In the first situation, when the orthographic projection of the first surface M1 on the underlayer 1 is a quadrilateral, the first cross section is parallel to a side of the quadrilateral, the intersection line of the first surface M1 and the first cross section is parallel to the same side of the quadrilateral. In this case, the number of protrusions provided at the intersection line of the first surface M1 and the first cross section is an odd number.

In the second situation, when the orthographic projection of the first surface M1 on the underlayer 1 is a quadrilateral, the first cross section is parallel to a diagonal of the quadrilateral, the intersection line of the first surface M1 and the first cross section is parallel to the same diagonal of the quadrilateral. In this case, the number of protrusions provided at the intersection line of the first surface M1 and the first cross section is an odd number.

In at least one embodiment of the present disclosure, for a photo spacer and a color filter pattern, the first surface M1 includes a center area and an edge area surrounding the center area, and the geometric center of the first surface M1 is located in the center area.

In the embodiment of the present disclosure, the center area at least includes a protrusion located at the geometric center of the first surface M1, and the edge area at least includes a plurality of protrusions located near the outer contour of the first surface M1.

The maximum distance between a part of the protrusions located in the center area and the underlayer 1 is greater than or equal to the maximum distance between a part of the protrusions located in the edge area and the underlayer 1.

Exemplarily, in the direction perpendicular to the plane of the underlayer 1, the average distance from the center area of the first surface M1 of the photo spacer to the underlayer 1 is large, and the average distance from the edge area of the first surface M1 of the photo spacer to the underlayer 1 is small; the height (PSH) of the part of the photo spacer located in the center area is larger, and the height (PSH) of the part of the photo spacer located in the edge area is smaller.

Exemplarily, in the direction perpendicular to the plane of the underlayer 1, the average distance from the center area of the first surface M1 of the color filter pattern to the underlayer 1 is large, and the average distance from the edge area of the first surface M1 of the color filter pattern to the underlayer 1 is small; the thickness of the part of the color filter pattern located in the center area is larger, and the thickness of the part of the color filter pattern located in the edge area is smaller. It should be noted that the first surface M1 of the color filter pattern refers to the surface on the side facing away from the underlayer 1 in the area not overlapping with the adjacent color filter pattern.

In at least one embodiment of the present disclosure, for a photo spacer, a plurality of protrusions are provided at the outer contour of the first surface M1, and the maximum distance between a part of the protrusions located at the outer contour of the first surface M1 and the underlayer 1 is less than or equal to the maximum distance between other protrusions and the underlayer 1.

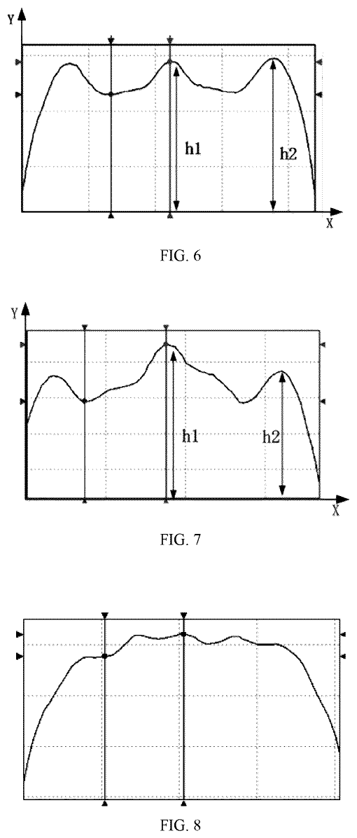

Exemplarily, as shown in FIG. 6, for a photo spacer, a plurality of protrusions are provided at the outer contour of the first surface M1, and the maximum distance h2 between a part of the protrusions located at the outer contour of the first surface M1 and the underlayer 1 is equal to the maximum distance h1 between other protrusions and the underlayer 1.

Exemplarily, as shown in FIG. 7, for a photo spacer, a plurality of protrusions are provided at the outer contour of the first surface M1, and the maximum distance h2 between a part of the protrusions located at the outer contour of the first surface M1 and the underlayer 1 is less than the maximum distance h1 between other protrusions and the underlayer 1.

The maximum distance h2 between the part of the protrusions located at the outer contour of the first surface M1 and the underlayer 1 as well as the maximum distance h1 between other protrusions and the underlayer 1 refer to average values.

It should be noted that, affected by the flatness of the underlying structure of the photo spacer in the display substrate and a measurement error of the detection equipment, the actual measured maximum distance h2 between the part of the protrusions located at the outer contour of the first surface M1 and the underlayer 1 as well as the maximum distance h1 between other protrusions and the underlayer 1 may fluctuate, and fluctuations within a range of 1.5% about the average value fall within the protection scope of the present disclosure.

In at least one embodiment of the present disclosure, for a photo spacer, the first surface M1 includes a center area and an edge area surrounding the center area, and the geometric center of the first surface M1 is located in the center area.

The curvature radius of a part of protrusions located in the center area is less than or equal to the curvature radius of a part of the protrusions located in the edge area.

It should be noted that the curvature radius of the part of protrusions located in the center area refers to an average curvature radius of the protrusions in this area, and the curvature radius of the part of protrusions located in the edge area refers to an average curvature radius of the protrusions in this area.

In at least one embodiment of the present disclosure, as shown in graph (2) of FIG. 4 and graph (2) of FIG. 5, when the organic structure includes a photo spacer, the photo spacer includes a side surface, which is an arc surface, and the intersection line of the side surface and the first cross section is arc D.

Taking the planar figure of the first surface M1 of the photo spacer being a quadrilateral as an example, the intersection line of the first surface M1 and the first cross section is parallel to the diagonal of the quadrilateral; or, the intersection line of the first surface M1 and the first cross section is parallel to the side of the quadrilateral.

In an exemplary embodiment, since the dimension of the first surface M1 of the photo spacer is less than or equal to the dimension of a second surface, which is arranged opposite to the first surface M1 and close to the underlayer 1, the side surface of the photo spacer is an annular are surface.

In at least one embodiment of the present disclosure, the curvature radius of the are gradually decreases in the direction away from the underlayer 1.

In the related art, at shown at a position marked with C in FIG. 1, the intersection line of the side surface and the first cross section is a straight line; the first cross section in FIG. 1 is a cross section that passes through the geometric center A of the first surface M1 and is perpendicular to the plane of the underlayer 1.

In the present disclosure, as shown at positions marked with D in graph (2) of FIG. 4 and graph (2) of FIG. 5, the intersection line of the side surface of the photo spacer and the first cross section is an arc. When the display substrate is prepared to form a display panel, if the display panel is compressed by an external force, compared with the side surface of the photo spacer of the related art as shown in FIG. 1, the photo spacer of the present disclosure can withstand greater pressure and has a better elastic recovery rate. This is because that the intersection line of the side surface of the photo spacer of the present disclosure and the first cross section is an are, that is, the slope of the side surface of the photo spacer gradually changes, and a slope angle of the side surface of the photo spacer provided by the embodiment of the present disclosure is smaller than the slope angle of the photo spacer in the related art.

By way of example, a photo spacer being the Sub PS is tested for illustration. Assuming that the height PSH of the Sub PS is 2.35 μm, and a length of the side of the first surface M1 (for example, the first surface M1 is a square), that is. Top CD, is 21 μm, under a load of 100 mN, the elastic recovery rate of the Sub PS in the related art is 80%, while the elastic recovery rate of the Sub PS provided in the embodiment of the present disclosure can be as high as 89.9%. The performance of the Sub PS provided by the embodiment of the present disclosure is significantly improved.

In at least one embodiment of the present disclosure, in the case where the organic structure includes a photo spacer, a distance between vertices of two adjacent protrusions in a direction parallel to the plane of the underlayer 1 is equal to ½˜⅙ of the dimension of the planar figure of the photo spacer in a preset direction, where the preset direction is a direction pointing to one of the two adjacent protrusions from the other one of the two adjacent protrusions.

The vertex of the protrusion refers to a point on the protrusion that has the largest distance to the underlayer 1 in the direction perpendicular to the plane of the underlayer.

Exemplarily, as shown in FIG. 6, the distance between the vertex of the protrusion on the left side and the vertex of the protrusion at the middle position is equal to ½ of the dimension of the first surface M1 in the preset direction, and the preset direction is a direction pointing from the protrusion on the left side to the protrusion at the middle position as shown in FIG. 6.

Exemplarily, as shown in graph (3) of FIG. 4, the distance between the vertex of the protrusion at the middle position and the vertex of the protrusion on the right side is equal to ¼ of the dimension of the first surface M1 in a preset direction, and the preset direction is a direction pointing to the protrusion on the right side from the protrusion at the middle position as shown in graph (3) of FIG. 4.

Exemplarily, when the preset direction is parallel to the intersection line of the first surface M1 and the first cross section, if the number of protrusions on the intersection line is 2N+1, then the average value of the distances between vertices of two adjacent protrusions is equal to ½N, where N is a positive integer.

Exemplarily, when the planar figure of the photo spacer is a quadrilateral, the dimension of the quadrilateral in the first direction and the dimension of the quadrilateral in the second direction are both in a range of 10 μm˜ 60 μm, and the first direction is perpendicular to the second direction. For example, the distance between vertices of two adjacent protrusions may be 15 μm, 12 μm, 11 μm, 10 μm, 8 μm, 6 μm, 5 μm, 3 μm.

In at least one embodiment of the present disclosure, the number of dents provided at the intersection line of the first surface M1 and the first cross section is an even number, and the number of protrusions is greater than the number of dents.

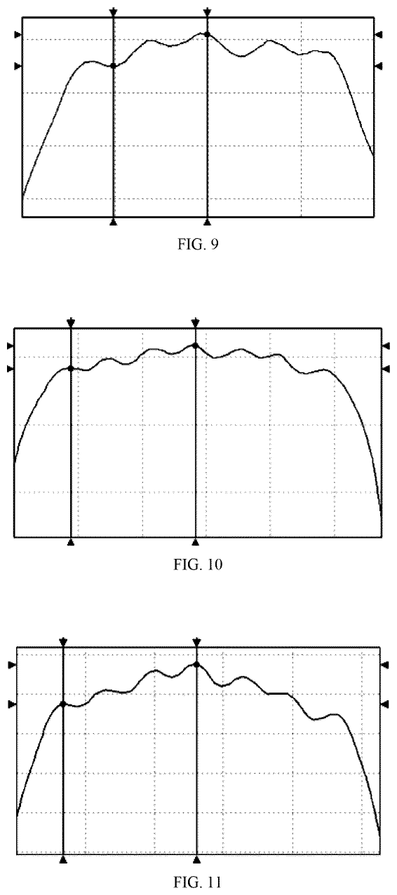

In at least one embodiment of the present disclosure, the number of protrusions provided at the intersection line of the first surface M1 and the first cross section is any one of 3 (for example, as shown in FIGS. 6 and 7), 5 (for example, as shown in FIGS. 8 and 9) and 7 (for example, shown in FIGS. 10 and 11).

In an exemplary embodiment, the orthographic projection of the first surface on the underlayer is a quadrilateral, when the intersection line of the first surface M1 and the first cross section is parallel to the diagonal of the quadrilateral, the number of protrusions provided at the intersection line of the first surface M1 and the first cross section is any one of 3, 5, and 7.

In an exemplary embodiment, the orthographic projection of the first surface on the underlayer is a quadrilateral, when the intersection line of the first surface M1 and the first cross section is parallel to the side of the quadrilateral, the number of protrusions provided at the intersection line of the first surface M1 and the first cross section is any one of 3, 5, and 7.

It should be noted that the above-mentioned quadrilateral includes but is not limited to a standard quadrilateral and a rounded quadrilateral.

In at least one embodiment of the present disclosure, the standard deviation of three times the dimension of the organic structure in the direction perpendicular to the plane of the underlayer 1 is less than or equal to 0.2 μm.

Exemplarily, assuming that the height of the organic structure (the height of the photo spacer PSH or the thickness of the color filter pattern THK) is 3 μm to 2 μm, the standard deviation of three times the dimension of the organic structure in the direction perpendicular to the plane of the underlayer 1 is less than or equal to 0.2 μm. In this case, the heights of the organic structures at different positions in the display substrate are very uniform, which improves the quality of the display substrate.

An embodiment of the present disclosure provides a display panel including the display substrate as described above.

The specific structure of the display substrate included in the display panel will not be described in detail herein, and reference may be made to the foregoing embodiments for details.

The display panel provided by the embodiment of the present disclosure includes a display substrate, due to the difference between the design of the organic structure and the preparation process, the first surface M1 is not an ideal plane, and the distances from various positions on the first surface M1 to the underlayer 1 are not exactly the same. In the present disclosure, the difference between the maximum distance between the first surface M1 of the organic structure and the underlayer 1 and the minimum spacing between the first surface M1 and the underlayer 1 is less than or equal to 0.06 μm, that is, the first surface M1 of the organic structure has relatively high flatness. Therefore, when a display panel prepared from the display substrate is pressed, the organic structure can play a better supporting role and the quality of the display panel is improved.

An embodiment of the present disclosure provides a display device including the display panel as described above. The display device may be a display device such as an LCD display, as well as any product or component with a display function such as a television, a digital camera, a mobile phone, a tablet computer including such display device.

Mask is a graphical master used in the field of photolithography. During the exposure process, the pattern of the mask is transferred to the corresponding product carrier. The photo spacer in the thin film transistor liquid crystal display (TFT-LCD) is a key structure for supporting the thickness of the box, and is generally prepared using a half tone mask (HTM) to reduce the process. The Full-Tone Pattern in the HTM is used to prepare the main photo spacer (Main PS), and the Half-Tone Pattern in the HTM is used to prepare the Sub photo spacer (Sub PS), thereby forming the step difference between the Main PS and the Sub PS. However, in the related art, the preparation of the HTM is difficult and the preparation cycle is long. In particular, the process of forming a chromium film in a predetermined area in the HTM to achieve the semi-transparent effect has an extremely high technical difficulty and the cost is extremely high.

In view of the above, an embodiment of the present disclosure provides a gray tone mask (GTM). In the gray tone mask, micro patterns are designed in a slit, the light source of the lithography machine passes through the micro patterns in the slit, so that the light intensity actually received by the lithography machine is reduced, thereby achieving a similar effect to the Half-Tone pattern in the HTM. The preparation cost of the GTM is low, the preparation cycle of the GTM is short, and a photo spacer formed by the GTM has better quality.

The mask provided by the embodiment of the present disclosure will be specifically introduced and explained below with reference to the accompanying drawings.

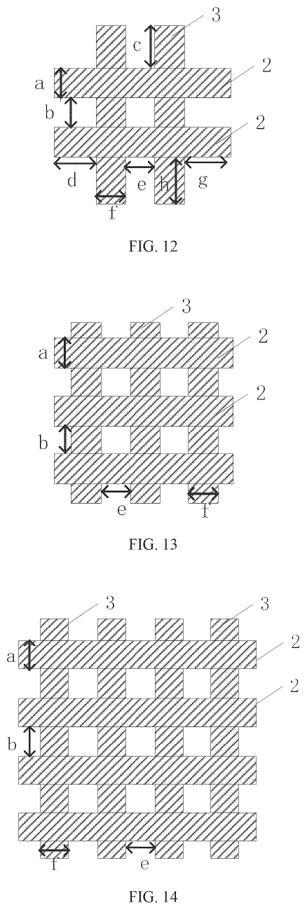

An embodiment of the present disclosure provides a mask used for preparing the display substrate as described above. The mask includes a plurality of first slits (not shown). As shown in FIGS. 12 to 15, the first slit is provided with a plurality of first light blocking bars 2 arranged in the same direction and a plurality of second light blocking bars 3 arranged in the same direction. The first light blocking bar 2 intersects with at least one second light blocking bar 3. The planar figure of the pattern in the first slit is a shape in mirror symmetry.

It should be noted that the patterns shown in FIGS. 12 to 15 are all micro patterns provided in the first slit.

In an exemplary embodiment, the mask is used to prepare the organic structure as described above, where the organic structure includes photo spacers and color filter structures.

When the mask is used to form photo spacers, the number of first slits in the mask is the same as the number of photo spacers. For example, the number of first slits is the same as the number of Sub PS, and the arrangement rule of the first slits is the same as that of the Sub PS.

When the mask is used to form color filter structures, for example, when it is used to form color filter structures (such as CF-R) located in the peripheral area BB, the number of the first slits in the mask is the same as that of the color filter structures (such as CF-R) located in the peripheral area BB, and the arrangement rule of the first slits in the mask is the same as that of the color filter structures (such as CF-R) located in the peripheral area BB.

Exemplarily, the mask may also include a plurality of second slits, and the second slits are full tone patterns. When the mask is used to form photo spacers, the second slits may be used to form the main PS. When the mask is used to form color filter patterns, the second slits are used to form color filter patterns located in the display area AA. The height of the main PS is greater than the height of the Sub PS, and the thickness of the color filter pattern located in the display area AA is greater than the thickness of the color filter pattern located in the peripheral area.

In an exemplary embodiment, the planar figure of the first light blocking bar 2 and the planar figure of the second light blocking bar 3 are both strips, for example, a rectangular.

In an exemplary embodiment, as shown in FIGS. 12 to 15, the width ‘a’ of the first light blocking bar 2 is equal to the width ‘f’ of the second light blocking bar 3.

In at least one embodiment of the present disclosure, the minimum spacing ‘b’ between two adjacent first light blocking bars 2 is different from the minimum spacing ‘e’ between two adjacent second light blocking bars 3.

In at least one embodiment of the present disclosure, the minimum spacing ‘b’ between two adjacent first light blocking bars 2 is equal to the minimum spacing ‘e’ between two adjacent second light blocking bars 3. In this specification, the situation in which the minimum spacing ‘b’ between two adjacent first light blocking bars 2 is equal to the minimum spacing ‘e’ between two adjacent second light blocking bars 3 is taken as an example for illustration.

The minimum spacing between two adjacent first light blocking bars 2 refers to a spacing between two adjacent first light blocking bars 2 in a direction perpendicular to the first light blocking bars 2. The meaning of the minimum spacing between two adjacent second light blocking bars 3 is similar to that mentioned above, and will not be described here.

The intersection of the first light blocking bar 2 with at least one second light blocking bar 3 includes but is not limited to the following situations.

In a first case, one first light blocking bar 2 intersects with one second light blocking bar 3, and the first light blocking bar 2 does not intersect with other second light blocking bars 3.

In a second case, one first light blocking bar 2 intersects with two second light blocking bar 3 respectively, and the first light blocking bar 2 does not intersect with other second light blocking bars 3.

In a third case, a first part of the first light blocking bars 2 intersects with a first part of the second light blocking bars 3, and a second part of the first light blocking bars 2 intersects with a second part of the second light blocking bars 3.

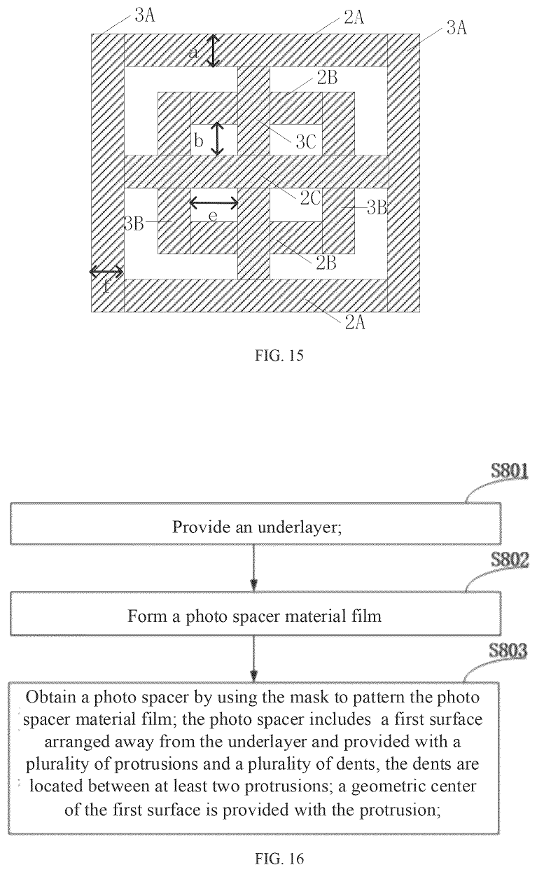

Exemplarily, as shown in FIG. 15, one first light blocking bar 2 (for example, the first light blocking bar marked as 2A in FIG. 15) intersects with three second light blocking bar 3 (including two second light blocking bars marked as 3A and one second light blocking bar marked as 3C) respectively, and such first light blocking bar 2 does not intersect with other second light blocking bars (for example the second light blocking bars marked as 3C).

In a fourth case, one of the first light blocking bars 2 intersects with all the second light blocking bars 3, and one of the second light blocking bars 3 intersects with all the first light blocking bars 2.

Exemplarily, as shown in FIGS. 12, 13 and 14, each first light blocking bar 2 intersects with all the second light blocking bars 3, and each second light blocking bar 3 intersects with all the second light blocking bars 3.

Exemplarily, as shown in FIG. 15, one of the first light blocking bars 2 (for example, the first light blocking bar marked as 2C) intersects with all the second light blocking bars 3; one of the second light blocking bars 3 (for example, the second light blocking bar marked as 3C) intersects with all the first light blocking bars 2.

In an exemplary embodiment, the mask provided by the embodiment of the present disclosure is mainly used to prepare photo spacers and color filter patterns. In order to take into account the simplicity of the planar figure of the photo spacer and the color filter structure as well as a better supporting effect, the planar figure of the pattern in the first slit of the mask is designed to be a shape in mirror symmetry, so as to prepare photo spacers and the color filter structures that have planar figure with mirror symmetry characteristics. It should be noted that in this specification, the planar figure of a certain structure refers to an orthographic projection figure of the structure on the underlayer 1 or the reference surface. The meanings of related descriptions in other positions are the same as here and will no longer be repeated.

The mask provided in the embodiment is a gray tone mask. In the gray tone mask, micro patterns are designed in a first slit, the light source of the lithography machine passes through the micro patterns in the slit, so that the light intensity actually received by the lithography machine is reduced, thereby achieving a similar effect to the Half-Tone pattern in the HTM. The preparation cost of the GTM is low, the preparation cycle of the GTM is short, and a photo spacer formed by the GTM has better quality.

In at least one embodiment of the present disclosure, as shown in FIGS. 12 to 15, the number of the first light blocking bars is the same as the number of the second light blocking bars.

Exemplarily, as shown in FIG. 12, the number of the first light blocking bars 2 and the number of the second light blocking bars 3 are both 2.

Exemplarily, as shown in FIG. 13, the number of the first light blocking bars 2 and the number of the second light blocking bars 3 are both 3.

Exemplarily, as shown in FIG. 14, the number of the first light blocking bars 2 and the number of the second light blocking bars 3 are both 4.

Exemplarily, as shown in FIG. 15, the number of the first light blocking bars 2 and the number of the second light blocking bars 3 are both 5.

In at least one embodiment of the present disclosure, as shown in FIGS. 12 to 15, the first light blocking bars 2 and the second light blocking bars 3 are arranged to be perpendicular to each other.

In at least one embodiment of the present disclosure, as shown in FIGS. 12 to 15, the minimum spacing ‘b’ between two adjacent first light blocking bars 2 is equal to the minimum spacing ‘e’ between two adjacent second light blocking bars 3, and the minimum spacing ‘b’ between two adjacent first light blocking bars 2 is greater than the width ‘a’ of the first light blocking bar.

Exemplarily, the width ‘a’ of the first light blocking bar 2 is greater than or equal to 1.0 #m, preferably, in a width range of 1 μm˜ 4 μm. For example, the width ‘a’ of the first light blocking bar may be 1.2 μm, 1.5 μm, 1.8 μm, 1.9 μm, 2.0 μm, 2.2 μm, 2.4 μm, 2.5 μm, 2.8 μm, 3.0 μm, 3.2 μm, 3.5 μm, 3.8 μm, 4.0 μm.

Exemplarily, the width ‘f’ of the second light blocking bar 3 is greater than or equal to 1.0 μm, preferably, in a width range of 1 μm˜ 4 μm. For example, the width ‘a’ of the first light blocking bar may be 1.5 μm, 1.8 μm, 1.9 μm, 2.0 μm, 2.2 μm, 2.4 μm, 2.5 μm, 2.8 μm, 3.0 μm, 3.2 μm, 3.5 μm, 3.8 μm, 4.0 μm.

In at least one embodiment of the present disclosure, the width ‘a’ of the first light blocking bar is equal to the width ‘f’ of the second light blocking bar.

Exemplarily, the minimum spacing ‘b’ between two adjacent first light blocking bars 2 ranges from 2.5 μm to 14 μm, preferably, 4 μm to 12 μm. For example, the minimum spacing ‘b’ between two adjacent first light blocking bars 2 is 4.2 μm, 4.5 μm, 4.8 μm, 5.0 μm, 5.2 μm, 5.5 μm, 5.8 μm, 6.0 μm, 6.3 μm, 6.5 μm, 6.8 μm, 7.0 μm, 7.3 μm, 7.5 μm, 7.8 μm, 8.0 μm, 8.3 μm, 8.5 μm, 8.8 μm, 9.0 μm, 9.5 μm, 9.8 μm, 10.0 μm, 10.3 μm, 10.5 μm, 10.8 μm, 11.0 μm, 11.3 μm, 11.5 μm, 11.8 μm, 12.0 μm.

Exemplarily, the minimum spacing ‘e’ between two adjacent second light blocking bars 3 ranges from 2.5 μm to 14 μm, preferably, 4 μm to 12 μm. For example, the minimum spacing ‘e’ between two adjacent second light blocking bars 3 is 4.2 μm, 4.5 μm, 4.8 μm, 5.0 μm, 5.2 μm, 5.5 μm, 5.8 μm, 6.0 μm, 6.3 μm, 6.5 μm, 6.8 μm, 7.0 μm, 7.3 μm, 7.5 μm, 7.8 μm, 8.0 μm, 8.3 μm, 8.5 μm, 8.8 μm, 9.0 μm, 9.5 μm, 9.8 μm, 10.0 μm, 10.3 μm, 10.5 μm, 10.8 μm, 11.0 μm, 11.3 μm, 11.5 μm, 11.8 μm, 12.0 μm.

Exemplarily, the minimum spacing ‘e’ between two adjacent second light blocking bars 3 is greater than the width ‘f’ of the second light blocking bar 3.

Exemplarily, the minimum spacing ‘e’ between two adjacent second light blocking bars 3 is equal to the width ‘f’ of the second light blocking bar 3.

Exemplarily, as shown in FIG. 12, the dimension ‘d’ of a first extension part of the first light blocking bar 2 is equal to the dimension ‘g’ of a second extension part thereof, and the dimension ‘c’ of a first extension part of the second light blocking bar 3 is equal to the dimension ‘h’ of a second extension part thereof. It should be noted that the dimensions marked as ‘d’, ‘g’, ‘c’, and h in FIG. 12 are related to the dimension of the planar figure of the organic structure (such as photo spacers or color filter patterns) prepared using the mask. The larger the above four dimensions, the larger the dimension of the corresponding planar figure of the organic structure.

In this specification, by way of example, four parameters, that is, the dimension ‘d’ of the first extension part of the first light blocking bar 2 and the dimension ‘g’ of the second extension part of the first light blocking bar 2, the dimension ‘c’ of the first extension part of the second light blocking bar 3 and the dimension ‘h’ of the second extension part of the second light blocking bar 3, are equal.

In at least one embodiment of the present disclosure, as shown in FIGS. 12 to 14, the structures and dimension of the first light blocking bars 2 and the second light blocking bars 3 are the same, and any first light blocking bar 2 intersects with all the second light blocking bars 3, and any second light blocking bar 3 intersects with all the first light blocking bars 2.

Exemplarily, the patterns in the first slit of the mask are all as shown in FIG. 12, the planar figures of the first light blocking bars 2 and the second light blocking bars 3 are both rectangular, and the areas of the two planar figures are the same; the number of the light blocking bars 2 and the number of the second light blocking bars 3 are both two. The geometric center of the pattern as shown in FIG. 12 is located in a hollow area surrounded by two first light blocking bars 2 and two second light blocking bars 3, and the hollow area can transmit light.

Exemplarily, the patterns in the first slit of the mask are all as shown in FIG. 13, the planar figures of the first light blocking bars 2 and the second light blocking bars 3 are both rectangular, and the areas of the two planar figures are the same; the number of the light blocking bars 2 and the number of the second light blocking bars 3 are both three. The geometric center of the pattern shown in FIG. 13 is located at the intersection of the first light blocking bars 2 and the second light blocking bars 3, that is, the geometric center is located in the non-hollow area.

Exemplarily, the patterns in the first slit of the mask are all as shown in FIG. 14, the planar figures of the first light blocking bars 2 and the second light blocking bars 3 are both rectangular, and the areas of the two planar figures are the same; the number of the light blocking bars 2 and the number of the second light blocking bars 3 are both four. The geometric center of the pattern shown in FIG. 14 is located at the intersection of the first light blocking bars 2 and the second light blocking bars 3, that is, the geometric center is located in the non-hollow area.

For the patterns shown in FIGS. 13 and 14, as the number of light blocking bars located in the first slit of the same size increases, the diffraction of light increases when the mask is used to prepare the organic structure. Therefore, the area of the organic structure corresponding to the non-hollow area of the mask may also receive light, and the stronger the diffraction effect, the stronger the light received by the area of the organic structure corresponding to the non-hollow area.

The organic structures (for example photo spacers and color filter patterns) prepared by the masks as shown in FIGS. 12-14 provided by the embodiments of the present disclosure can greatly improve the problem of a single large dent (also called a crater) appearing at the geometric center of the first surface M1 of the organic structure in the related art, and can greatly improve the surface flatness and thickness uniformity of the organic structure, thereby improving the supporting effect of the organic structure and improving the quality of the organic structure.

In at least one embodiment of the present disclosure, as shown in FIG. 15, the first light blocking bars 2 include a first group (the first light blocking bars marked as 2A), a second group (the first light blocking bars marked as 2B) and a third group (the first light blocking bar marked as 2C); the second light blocking bars 3 include a first group (the second light blocking bars marked as 3A), a second group (the second light blocking bars marked as 3B) and a third group (the second light blocking bar marked as 3C).

The first group of first light blocking bars and the second group of first light blocking bars respectively include two first light blocking bars 2. The first group of second light blocking bars and the second group of second light blocking bars respectively include two second light blocking bars. The third group of first light blocking bars includes one first light blocking bar, and the third group of second light blocking bars includes one second light blocking bar.

The first group of first light blocking bars 2A and the first group of second light blocking bars 3A intersect to form a first closed ring, and the second group of first light blocking bars 2B and the second group of second light blocking bars 3B intersect to form a second closed ring. The second closed ring is located inside the first closed ring. The third group of first light blocking bar 2C and the third group of second light blocking bar 3C intersect, and they intersect with the first closed ring and the second closed ring respectively. The geometric center of the mask is located at the intersection of the third group of first light blocking bar 2C and the third group of second light blocking bar 3C.

In the embodiment of the present disclosure, the edge of the pattern in the first slit of the mask is configured to be a closed shape (such as the above-mentioned first closed ring and the second closed ring), so that the exposure controllability at the edge area of the organic structure can be greatly improved. Therefore, the edge area of the organic structure can be evenly exposed, and the thickness uniformity of the edge area of the organic structure is improved. In addition, in combination with configuring the third group of first light blocking bar 2C and the third group of second light blocking bar 3C to intersect and both of them intersecting with the first closed ring and the second closed ring respectively, the middle area of the organic structure obtained by exposure with the mask also has high thickness uniformity. The organic structure prepared by the mask has high process stability, controllability and good quality. The mask has low cost and short preparation cycle. As can be found by comparison, the cost and preparation cycle of this mask are reduced by 50% or more compared with the HTM in related technologies.

An embodiment of the present disclosure provides a method for preparing a display substrate. As shown in FIG. 16, the method includes steps described below.

At S801, a underlayer 1 is provided.

The material of the underlayer 1 is not limited herein. For example, the material of the underlayer 1 may be a rigid material, such as glass; or the material of the underlayer 1 may be a flexible material, such as polyimide.

At S802, a photo spacer material film is formed.

A coating process may be used to form an entire surface of photo spacer material film.

At S803, a mask as described above is used to pattern the photo spacer material film to obtain a photo spacer. The photo spacer includes a first surface M1 located away from the underlayer 1, and a plurality of protrusions and a plurality of dents are provided on the first surface M1, and the dents are located between at least two protrusions. A protrusion is provided at the geometric center of the first surface M1. In a direction perpendicular to the plane of the underlayer 1, the difference between the maximum distance between the first surface M1 and the underlayer 1 and the minimum distance between the first surface M1 and the underlayer 1 is less than or equal to 0.06 μm.

The above-mentioned mask refers to the gray tone mask (GTM) provided by the embodiment of the present disclosure. For the specific structure of the GTM, please refer to the previous introduction and will not be described here.

The type of the photo spacer is not limited herein. For example, the photo spacer may be a main photo spacer (Main PS); for another example, the photo spacer may be a Sub photo spacer (Sub PS). By way of example, in the embodiment, the photo spacer prepared by the mask is the Sub PS.

Due to the difference between the design of the organic structure and the preparation process, the first surface M1 is not an ideal plane, and the distances from various positions on the first surface M1 to the underlayer 1 are not exactly the same. For the organic structure prepared by the above preparation method provided in the present disclosure, the difference between the maximum distance between the first surface M1 of the organic structure and the underlayer 1 and the minimum distance between the first surface M1 and the underlayer 1 is less than or equal to 0.06 μm, that is, the first surface M1 of the organic structure has relatively high flatness. Therefore, when a display panel prepared from the display substrate is pressed, the organic structure can play a better supporting role and the quality of the display panel is improved.

It should be noted that both the photo spacer and the color filter pattern located in the peripheral area BB can play a supporting role.

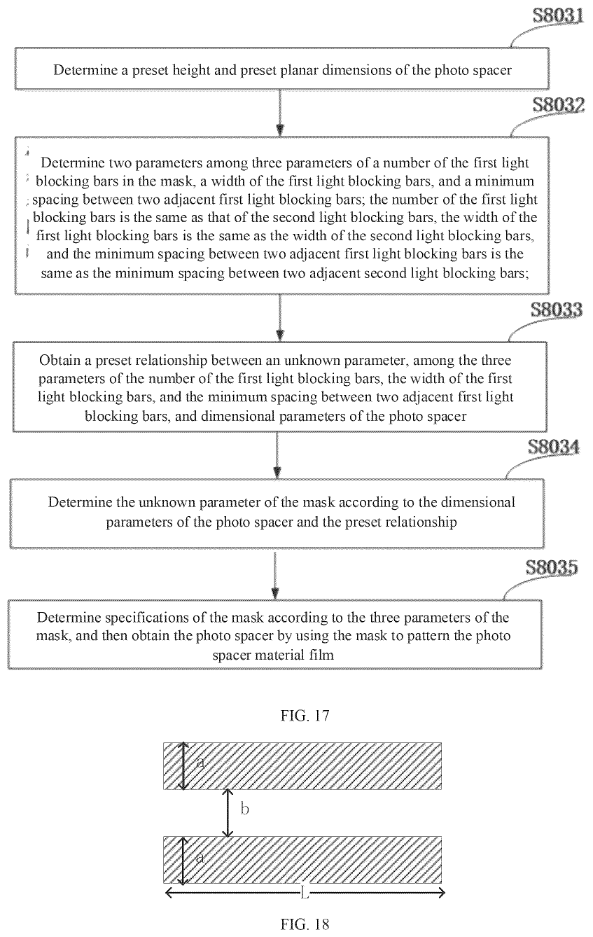

In at least one embodiment of the present disclosure, as shown in FIG. 17, the step S803, in which a mask as described above is used to pattern the photo spacer material film to obtain a photo spacer, includes steps described below.

At S8031, a preset height and preset plane dimensions of the photo spacer is determined.

In practical applications, the required preset height and preset plane dimensions of the photo spacer are calculated based on the type of product and product design.

At S8032, two of three parameters, that is, the number of first light blocking bars 2 in the mask, the width ‘a’ of the first light blocking bar 2, and the minimum spacing between two adjacent first light blocking bars 2, are determined. The number of the first light blocking bars 2 is the same as the number of the second light blocking bars 3, the width ‘a’ of the first light blocking bars 2 is the same as the width ‘f’ of the second light blocking bars 3, and the minimum spacing ‘b’ between two adjacent first light blocking bars 3 is the same as the minimum spacing ‘e’ between two adjacent second light blocking bars 3.

Based on the preset height and preset plane dimensions of the photo spacer, the shape and dimension of the pattern in the first slit of a mask that is designed for preparing the photo spacer of such specification are determined.

In the embodiment of the present disclosure, before determining two of the number of first light blocking bars 2 in the mask, the width ‘a’ of the first light blocking bars 2, and the minimum spacing between two adjacent first light blocking bars 2, other parameters besides the above three parameters need to be set. Then, an influence trend of changes in the above three parameters on the preset height and preset plane dimensions of the photo spacer is studied. Combined with the difficulty and cost of the preparation process of the mask, two of the above three parameters are determined, and then the influence trend of changes in the remaining parameter (unknown parameter) on the dimensional parameters (height and plane dimensions) of the photo spacer is discussed.

At S8033, a preset relationship between the unknown parameters among the number of first light blocking bars 2, the width ‘a’ of the first light blocking bars 2, and the minimum spacing ‘b’ between two adjacent first light blocking bars 2 and the dimensional parameters of the photo spacer is obtained.

The preset relationship between the unknown parameters among the number of first light blocking bars 2, the width ‘a’ of the first light blocking bars 2, and the minimum spacing ‘b’ between two adjacent first light blocking bars 2 and the dimensional parameters of the photo spacer may be obtained through simulation calculations and experimental tests. For example, a preset relationship curve can be obtained.

At S8034, the unknown parameter of the mask is determined according to the dimensional parameters and preset relationship of the photo spacer.

The dimensional parameters of the photo spacer include height PSH, the dimension in the first direction TX and the dimension in the second direction TY. The height PSH of the photo spacer decreases as the minimum spacing ‘b’ between two adjacent first light blocking bars 2 increases, and the planar dimension of the photo spacer increases as the minimum spacing ‘b’ between two adjacent first light blocking bars 2 increases. The minimum spacing ‘b’ between two adjacent first light blocking bars 2 is the same as the minimum spacing ‘e’ between two adjacent second light blocking bars 3.

At S8035, the specifications of the mask is determined according to the three parameters of the mask, and then the mask is used to pattern the photo spacer material film to obtain the photo spacer.

In at least one embodiment of the present disclosure, the step S8032, in which two of the three parameters, the number of first light blocking bars 2 in the mask, the width ‘a’ of the first light blocking bars 2, and the minimum spacing between two adjacent first light blocking bars 2, are determined, includes:
sub-step 1, determining the number of first light blocking bars 2 in the mask and the width ‘a’ of the first light blocking bars 2;

In at least one embodiment of the present disclosure, S8033, in which a preset relationship between the unknown parameters among the number of first light blocking bars 2, the width ‘a’ of the first light blocking bars 2, and the minimum spacing ‘b’ between two adjacent first light blocking bars 2 and the dimensional parameters of the photo spacer is obtained, includes:
sub-step 1, obtaining the preset relationship between the minimum spacing ‘b’ between two adjacent first light blocking bars 2 and the dimensional parameters of the photo spacer; where the dimensional parameters include height PSH and plane dimensions.

In at least one embodiments of the present disclosure, the height PSH of the photo spacer decreases as the minimum spacing ‘b’ between two adjacent first light blocking bars 2 increases, and the planar dimension of the photo spacer increases as the minimum spacing ‘b’ between two adjacent first light blocking bars 2 increases. The minimum spacing ‘b’ between two adjacent first light blocking bars 2 is the same as the minimum spacing ‘e’ between two adjacent second light blocking bars 3.

In at least one embodiment of the present disclosure, the planar dimensions of the photo spacer include the dimension TX in the first direction and the dimension TY in the second direction, and the first direction is perpendicular to the second direction. The dimension TX in the first direction increases as the minimum spacing ‘b’ between two adjacent first light blocking bars 2 increases, and the dimension TY in the second direction increases as the minimum spacing ‘b’ between two adjacent first light blocking bars 2 increases. The second direction is consistent with the extension direction of the first light blocking bar 2, and the first direction is consistent with the extension direction of the second light blocking bar 3.

Hereinafter, a process of determining the specific specifications of the mask and the relationship between various specification parameters in the mask and the dimensions of the photo spacer will be introduced in detail.

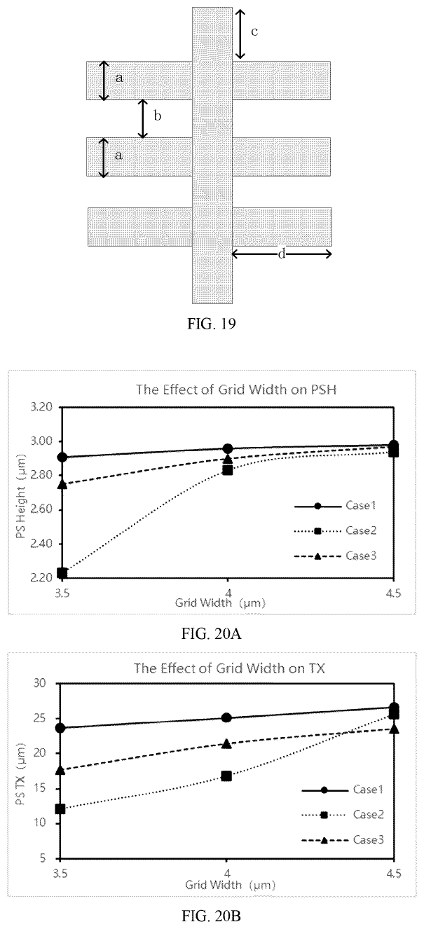

Before determining the available patterns in the first slit of the mask, three preliminary pattern styles as shown in FIG. 18, FIG. 19 and FIG. 12 are provided. Hereinafter, by way of example, the pattern in the first slit is used to prepare the Sub PS.

The width of the light blocking bar (also called as grid) is a direct factor that affects the projected light flux, and significantly affects the height and dimensions of the photo spacer formed after light curing of organic materials. The width limit of the light blocking bar depends on the resolution of the mask preparation process, and when the width of the light blocking bar in the mask is close to the resolution limit of 1 μm, the uniformity of the line width (width) of the photo spacer prepared by the mask will deteriorate, which is not conducive to improving the uniformity of large-size products. Therefore, in the early simulation calculation, the width ‘a’ of the light blocking bar, which is greater than or equal to 2.5 μm, is used for simulation. calculation.

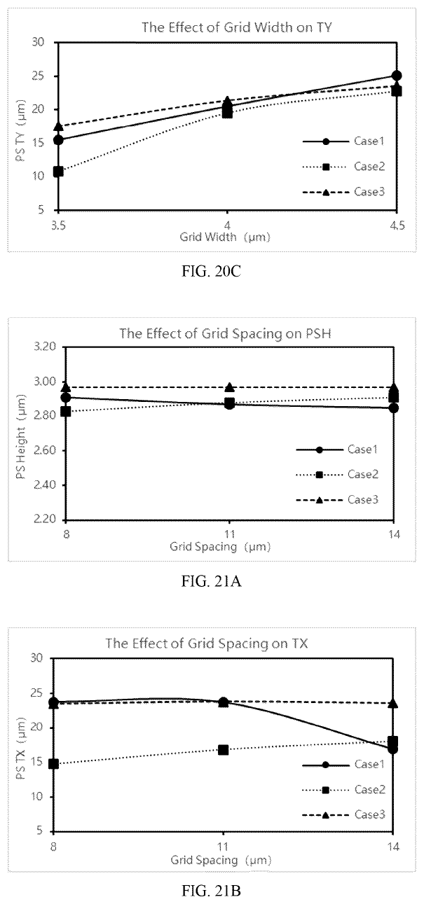

The effect of the changes in the width of the light blocking bar on the height and dimensions of the photo spacer PS is studied when other parameters are fixed, and the results are shown in FIG. 20A, FIG. 20B and FIG. 20C. FIG. 20A shows a curve of the height PSH of the photo spacer PS as the width ‘a’ (Grid Width) of the light blocking bar changes. FIG. 20B is a curve of the dimension TX of the photo spacer PS in the first direction as the width ‘a’ of the light blocking bar changes. FIG. 20C is a curve of the dimension TY of the photo spacer PS in the second direction as the width ‘a’ of the light blocking bar changes. Among them, the curve marked as Case1 is the result calculated using the mask pattern as shown in FIG. 18, the curve marked as Case2 is the result calculated using the mask pattern shown in FIG. 19, and the curve marked as Case3 is the result calculated using the mask pattern shown in FIG. 12.

As can be seen from FIG. 20A, FIG. 20B and FIG. 20C, the height PSH of the photo spacer PS changes non-linearly with the arrangement shape of the light blocking bars and the width ‘a’ of the light blocking bars. When the width ‘a’ of the light blocking bar is large, the area occupied by the gray zone of the mask is small, and the height of the photo spacers PS prepared by the masks with different arrangement shapes gradually approaches to each other. It can be inferred that the width ‘a’ of the light blocking bar is a direct factor affecting the area of the gray zone and is related to the formation of the step difference between the photo spacers, where the step difference refers to the height difference between the main PS and the Sub PS.

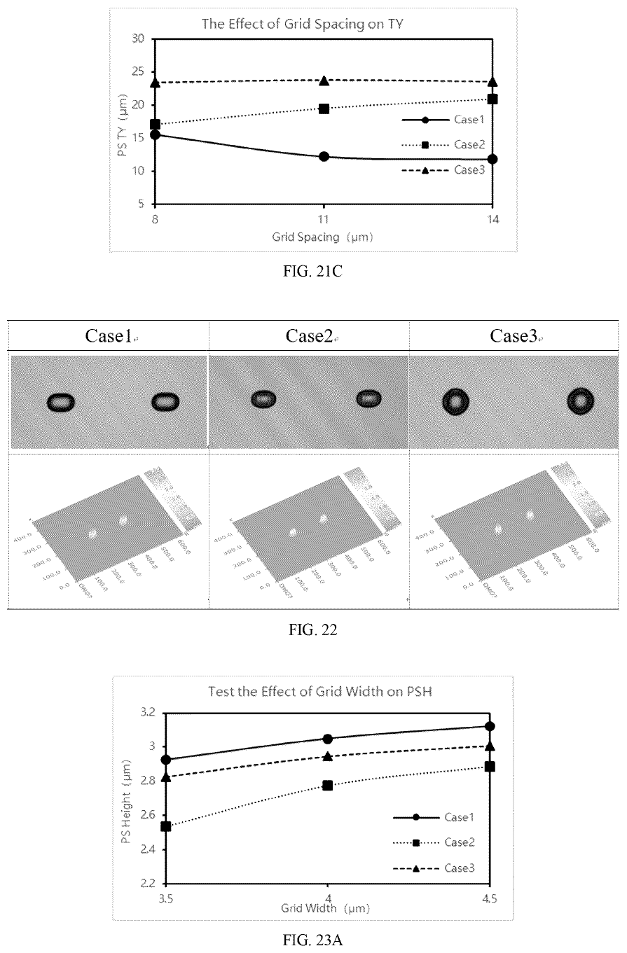

Assuming that the width ‘a’ of the light blocking bars is 3.5 μm, the effect of the spacing ‘b’ (Grid Spacing) between the light blocking bars on the height and dimensions of the photo spacer PS is further simulated and calculated, and the simulation results are shown in FIG. 21A, FIG. 21B and FIG. 21C. Among them, FIG. 21A shows a variation curve of the height PSH of the photo spacer PS with the spacing ‘b’ between the light blocking bars. FIG. 21B is a variation curve of the dimension TX of the photo spacer PS in the first direction with the spacing ‘b’ between the light blocking bars. FIG. 21C is a variation curve of the dimension TY of the photo spacer PS in the second direction with the spacing ‘b’ between the light blocking bars. Among them, the curve marked as Case1 is the result calculated using the mask pattern as shown in FIG. 18, the curve marked as Case2 is the result calculated using the mask pattern shown in FIG. 19, and the curve marked as Case3 is the result calculated using the mask pattern shown in FIG. 12.

As can be seen from FIG. 21A, FIG. 21B and FIG. 21C, in the curves marked as Case3, as the spacing ‘b’ between the light blocking bars changes, the height PSH of the photo spacer PS, the dimension TX of the photo spacer PS in the first direction, and the dimension TY of the photo spacer PS in the second direction have the smallest change range and the highest stability.

In order to further verify the accuracy of the above conclusion, the mask pattern shown in FIG. 18, the mask pattern shown in FIG. 19, and the mask pattern shown in FIG. 12 are used to actually prepare photo spacers, and corresponding parameters are measured. Referring to FIG. 22, there is shown a top structural view and a 3D scan of a photo spacer prepared using the above three mask patterns. In the top view of the photo spacer prepared using the mask pattern as shown in FIG. 12, the shape of the PS is close to the rounded corner direction (or approximately circular), which is consistent with the TX and TY dimensions calculated by simulation in FIG. 21B and FIG. 21C.

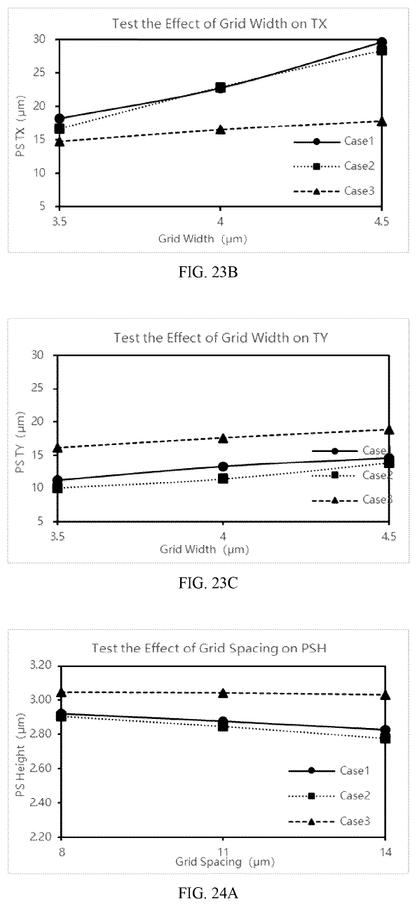

The actual measurement results of the height and dimensions of the spacer PS changing with the width ‘a’ of the light blocking bars are shown in FIG. 23A, FIG. 23B and FIG. 23C. FIG. 23A shows a variation curve of the height PSH of the photo spacer PS with the width ‘a’ (Grid Width) of the light blocking bar changes. FIG. 23B is a variation curve of the dimension TX of the photo spacer PS in the first direction with the width ‘a’ of the light blocking bar. FIG. 23C is a variation curve of the dimension TY of the photo spacer PS in the second direction with the width ‘a’ of the light blocking bar. Among them, the curve marked as Case1 is the actual measurement result of the photo spacer prepared using the mask pattern as shown in FIG. 18, and the curve marked as Case2 is the actual measurement result of the photo spacer prepared using the mask pattern shown in FIG. 19, the curve marked as Case 3 is the actual measurement result of the photo spacer prepared using the mask pattern as shown in FIG. 12.

In the drawings of this specification, Grid Width represents the width ‘a’ of the light blocking bars, and Grid Spacing represents the spacing ‘b’ between two adjacent light blocking bars, and will not be described again.

According to FIG. 23A, FIG. 23B and FIG. 23C, it can be seen that the measured results are close to the simulation calculation results. By considering the changing rules of the height PSH of the photo spacer PS, the dimension TX of the photo spacer PS in the first direction, and the dimension TY of the photo spacer PS in the second direction comprehensively, three parameters of the PS prepared through case3 (the mask pattern shown in FIG. 12 is used) has small changes with the width ‘a’ of the light blocking bars, and the stability is this case is higher.

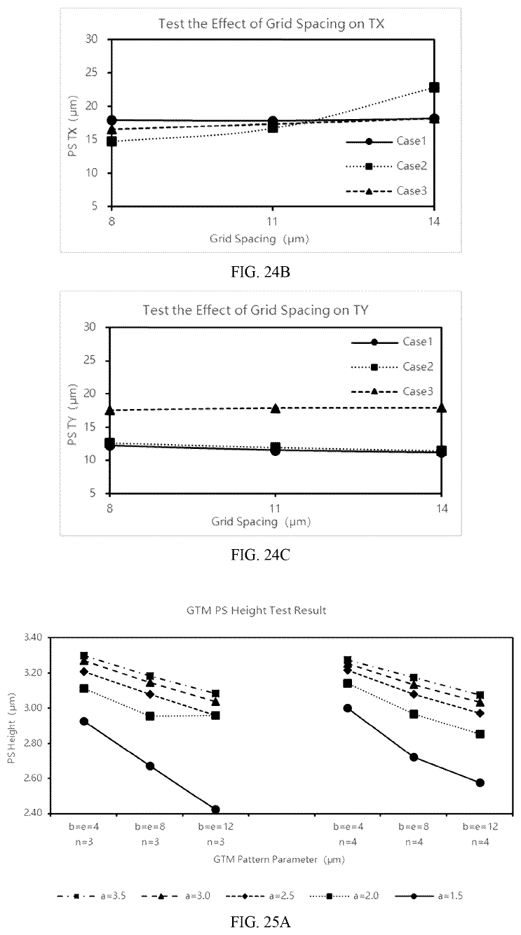

The actual measurement results of the height and dimensions of the PS changing with the spacing ‘b’ between light blocking bars are shown in FIG. 24A, FIG. 24B and FIG. 24C. FIG. 24A shows a variation curve of the height PSH of the photo spacer PS with the width ‘a’ (Grid Width) of the light blocking bars. FIG. 24B is a variation curve of the dimension TX of the photo spacer PS in the first direction with the width ‘a’ of the light blocking bar. FIG. 24C is a variation curve of the dimension TY of the photo spacer PS in the second direction with the width ‘a’ of the light blocking bar. Among them, the curve marked as Case1 is the actual measurement result of the photo spacer prepared using the mask pattern as shown in FIG. 18; the curve marked as Case2 is the actual measurement result of the photo spacer prepared using the mask pattern as shown in FIG. 19; the curve marked as Case3 is the actual measurement result of the photo spacer prepared using the mask pattern as shown in FIG. 12.

According to FIG. 24A, FIG. 24B and FIG. 24C, it can be seen that the measured results are close to the simulation calculation results. By considering the changing rules of the height PSH of the photo spacer PS, the dimension TX of the photo spacer PS in the first direction, and the dimension TY of the photo spacer PS in the second direction comprehensively, three parameters of the PS prepared through case1 (the mask pattern shown in FIG. 18 is used) and case3 (the mask pattern shown in FIG. 12 is used) have small changes with the width ‘a’ of the light blocking bars, and the stability is these cases is higher.

Based on the above simulation calculations and actual measurement results of the width ‘a’ of the light blocking bars and the spacing ‘b’ between the light blocking bars, it is determined that the three parameters of the photo spacer prepared through case3 (the mask pattern shown in FIG. 12) have the highest stability.

Hereinafter, the effects of the number ‘n’ of the light blocking bars, the width ‘a’ of the light blocking bars, and the spacing ‘b’ between the light blocking bars on the height PSH of the photo spacer PS, the dimension TX of the PS in the first direction, and the dimension TY of the PS in the second direction are studied based on the mask pattern shown in FIG. 12. In the mask pattern shown in FIG. 12, n is 2 (two first light blocking bars 2 and two second light blocking bars 3). In the mask pattern shown in FIG. 13, n is 3 (three first light blocking bars 2 and three second light blocking bars 3). In the mask pattern shown in FIG. 14, n is 4 (four first light blocking bars 2 and four second light blocking bars 3).

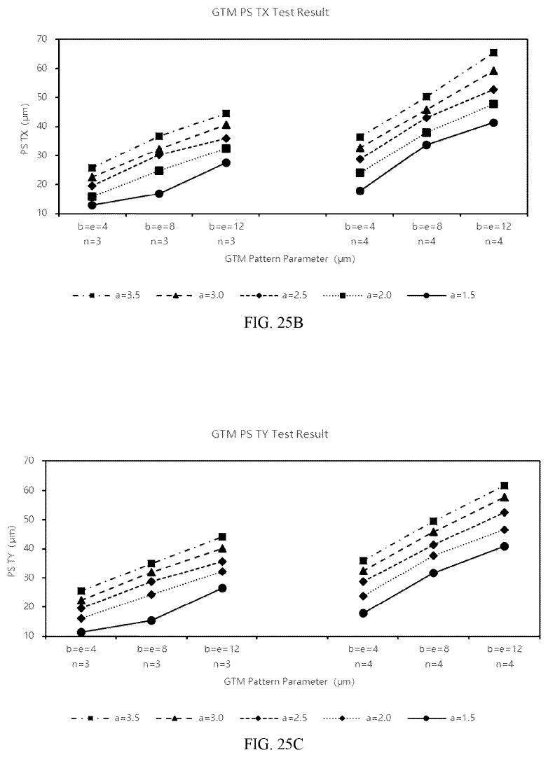

FIG. 25A shows curves illustrating effects of the width ‘a’ of the light blocking bars on the height PSH of the photo spacer when the number ‘n’ of the light blocking bars and the spacing ‘b’ between the light blocking bars are determined. FIG. 25B shows curves illustrating effects of the width of the light blocking bars on the first-direction dimension TX when the number ‘n’ of the light blocking bars and the spacing ‘b’ between the light blocking bars are determined. FIG. 25C shows curves illustrating effects of the width of the light blocking bars on the second-direction dimension TY when the number ‘n’ of the light blocking bars and the spacing ‘b’ between the light blocking bars are determined. Among them, the five curves on the left side in FIG. 25A. FIG. 25B and FIG. 25C are all test results of the photo spacers prepared using the mask as shown in FIG. 13 (n=3), the five curves on the right side in FIG. 25A, FIG. 25B and FIG. 25C are all test results of the photo spacers prepared using the mask as shown in FIG. 14 (n=4).

As can be seen from the results in FIG. 25A, FIG. 25B and FIG. 25C, as the width ‘a’ of the light blocking bars increases, the height of the photo spacer PSH, the first-direction dimension TX and the second-direction dimension TY all increase. In addition, as the spacing ‘b’ between the light blocking bars increases, the height PSH of the photo spacer decreases, and the first-direction dimension TX of the photo spacer and the second-direction dimension TY of the photo spacer both increase; when the number ‘n’ of light blocking bars increases (for example, from n=2 to n=3 and n=4), the adjusting ability of the mask pattern on the light flux becomes stronger, and the adjustment range of the height PSH of the photo spacer changes from 0.3 μm (mask in FIG. 12) to 0.8 μm (mask in FIGS. 13 and 14).

Exemplarily, when the width ‘a’ of the light blocking bars is 1.5 μm, the luminous flux can be effectively reduced by increasing the spacing ‘b’ between the light blocking bars, thus a semi-transparent effect of 12% relative to the characteristic value of the PS made using the HTM process in related technologies can be achieved.

Exemplarily, as can be seen from the results in FIG. 25B and FIG. 25C, the dimension TX of the photo spacer in the first direction and the dimension TY of the photo spacer in the second direction range from 10 μm to 60 μm, which can meet the dimension requirements of photo spacers in current display products.

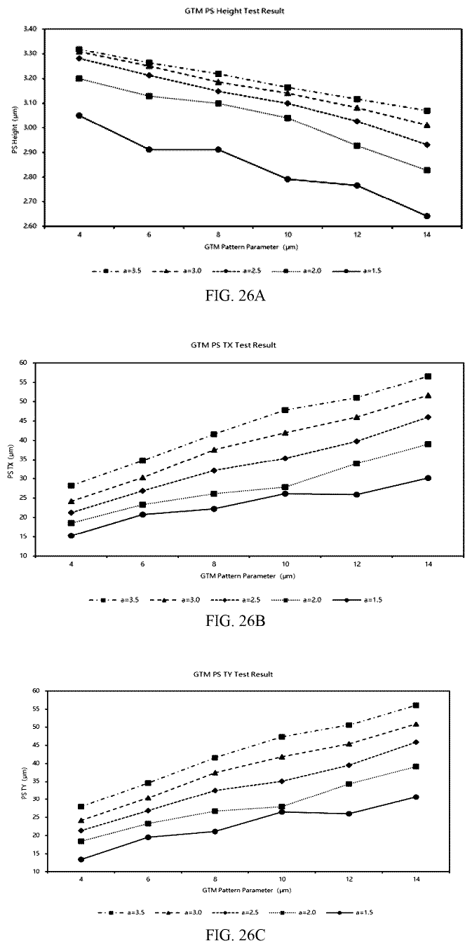

FIG. 26A shows a variation curve of the height PSH of the photo spacer with the spacing ‘b’ between the light blocking bars when the mask pattern shown in FIG. 15 is used and the width ‘a’ of the light blocking bars is determined. FIG. 26B shows a variation curve of the dimension TX of the photo spacer in the first direction with the spacing ‘b’ between the light blocking bars when the mask pattern shown in FIG. 15 is used and the width ‘a’ of the light blocking bars is determined. FIG. 26C, shows a variation curve of the dimension TY of the photo spacer in the second direction with the spacing ‘b’ between the light blocking bars when the mask pattern shown in FIG. 15 is used and the width ‘a’ of the light blocking bars is determined.

As can be seen from the results in FIG. 26A, FIG. 26B and FIG. 26C, for the photo spacer prepared with the mask pattern shown in FIG. 15, the height PSH of the photo spacer decreases as the spacing ‘b’ between the light blocking bars increases, the height PSH of the photo spacer decreases as the width ‘a’ of the light blocking bar decreases; the dimension TX of the photo spacer in the first direction increases as the spacing ‘b’ between the light blocking bars increases, and the dimension TX of the photo spacer in the first direction decreases as the width ‘a’ of the light blocking bars decreases; the dimension TY in the second direction of the photo spacer increases as the spacing ‘b’ between the light blocking bars increases, the dimension TY in the direction of the PS decreases as the width ‘a’ of the light blocking bars decreases.

It should be noted that in current display products, a step difference between the main PS and the Sub PS is required, and the step difference is set to be in a range of 0.5 μm˜0.7 μm.

In addition, on the basis of optimizing the mask pattern, this specification only lists the data under the changing conditions of the number ‘n’ of light blocking bars, the width ‘a’ of the light blocking bars, and the spacing b/e between the light blocking bars. When the length L of the light blocking bars, c/d change, TX/TY will also significantly increase to form a larger supporting area, which will not be listed here.

It should be noted that in this application, explanation is made by taking the situation where the spacing ‘b’ between the light blocking bars is equal to the spacing ‘e’ between the light blocking bars as an example.

In order to facilitate actual operation, formulas are obtained by simulating the rules mentioned above to facilitate the determination of the relationship between the parameters of the mask and the dimensional parameters of the photo spacer under different circumstances.

When the number ‘n’ of the light blocking bars is a fixed value, as the width ‘a’ of the light blocking bars and the spacing b (e) between the light blocking blocks change, the PS characteristic value shows a certain linear change trend, which is specifically expressed as:

$$( 1 ) n = 3 , a = 3.5 , PSH = - 0.0269 * b + 3.403 ; \\ TX = 2.365 * b + 16.694 ; TY = 2.3096 * b + 16.331 ;$$

$$( 2 ) n = 3 , a = 3. , PSH = - 0.0288 * b + 3.381 ; \\ TX = 2.2604 * b + 13.651 ; TY = 2.2098 * b + 13.832 ;$$

$$( 3 ) n = 3 , a = 2.5 , PSH = - 0.0309 * b + 3.3315 ; \\ TX = 2.0353 * b + 12.246 ; TY = 1.9893 * b + 12.068 ;$$

$$( 4 ) n = 3 , a = 2. , PSH = - 0.0216 * b + 3.1873 ; \\ TX = 2.0805 * b + 7.7562 ; TY = 1.9865 * b + 8.33 ;$$

$$( 5 ) n = 3 , a = 1.5 , PSH = - 0.0629 * b + 3.1782 ; \\ TX = 1.8273 * b + 4.45 ; TY = 1.9081 * b + 2.4918 ;$$

$$( 6 ) n = 4 , a = 3.5 , PSH = - 0.0246 * b + 3.3718 ; \\ TX = 3.6348 * b + 21.553 ; TY = 3.2129 * b + 23.451 ;$$

$$( 7 ) n = 4 , a = 3. , PSH = - 0.0276 * b + 3.3603 ; \\ TX = 3.3148 * b + 19.344 ; TY = 3.1471 * b + 20.105 ;$$

$$( 8 ) n = 4 , a = 2.5 , PSH = - 0.0301 * b + 3.3305 ; \\ TX = 3.0049 * b + 17.494 ; TY = 2.9698 * b + 17.071 ;$$

$$( 9 ) n = 4 , a = 2. , PSH = - 0.0364 * b + 3.2797 ; \\ TX = 2.9894 * b + 12.724 ; TY = 2.8358 * b + 13.243 ;$$

$$( 10 ) n = 4 , a = 1.5 , PSH = - 0.0529 * b + 3.1888 ; \\ TX = 2.9267 * b + 7.5587 ; TY = 2.8798 * b + 7.0863 ;$$

When the number ‘n’ of the light blocking bars/width ‘a’ is determined, PSH, TX, TY show a certain linear relationship with relative to the spacing ‘b’ between light blocking bars. According to the above formulas, when the specifications (including height and planar dimensions) of the photo spacer PS are determined, the number of the light blocking bars in the mask required and the detailed dimensions thereof can be accurately and quickly calculated to facilitate the design and preparation of the mask.

In order to further study the comprehensive effect of the width ‘a’ of the light blocking bars and the spacing ‘b’ between the light blocking bars on the optical density (the amount of light that actually transmits through the mask and irradiates on the photo spacer material film), based on the above calculation and analysis, the width ‘a’ of the light blocking bars and the spacing ‘b’ between the light blocking bars are further fitted. According to parameter results of the actual exposure, for the linear relationship between the characteristic values of the photo spacer (PSH, TX, TY) and the spacing ‘b’ between the light blocking bars, the slope and intercept can be expressed by the fourth-order formula of the width ‘a’ of the light blocking bars, which is expressed as:
when n=3, it corresponds to the mask pattern as shown in FIG. 13;

$$( 1 ) PSH = ( - 0.0491 \times {a}^{4} + 0.5243 \times {a}^{3} - 2.0569 \times {a}^{2} + 3.5057 \times a - 2.2144 ) \times b + ( 0.198 \times {a}^{4} - 2.0884 \times {a}^{3} + 7.9991 \times {a}^{2} - 12.992 \times a + 10.714 )$$

$$( 2 ) TX = ( - 0.6397 \times {a}^{4} + 6.5153 \times {a}^{3} - 24.176 \times {a}^{2} + 38.851 \times a - 20.802 ) \times b + ( 5.9941 \times {a}^{4} - 59.638 \times {a}^{3} + 214.84 \times {a}^{2} - 324.79 \times a + 179.18 )$$

$$( 3 ) TY = ( - 0.4211 \times {a}^{4} + 4.1813 \times {a}^{3} - 15.026 \times {a}^{2} + 23.284 \times a - 11.189 ) \times b + ( 1.7219 \times {a}^{4} - 15.329 \times {a}^{3} + 46.016 \times {a}^{2} - 45.255 \times a + 9.856 )$$

when n=4, it corresponds to the mask pattern as shown in FIG. 14;

$$( 1 ) PSH = ( - 0.0014 \times {a}^{4} + 0.0211 \times {a}^{3} - 0.1132 \times {a}^{2} + 0.2645 \times a - 0.2591 ) \times b + ( - 0.0109 \times {a}^{4} + 0.1239 \times {a}^{3} - 0.5583 \times {a}^{2} + 1.2291 \times a + 2.2385 )$$

$$( 2 ) TX = ( - 0.4162 \times {a}^{4} + 4.1997 \times {a}^{3} - 15.198 \times {a}^{2} + 23.575 \times a - 10.307 ) \times b + ( 3.8691 \times {a}^{4} - 38.188 \times {a}^{3} + 134.51 \times {a}^{2} - 191.86 \times a + 101.99 )$$

$$( 3 ) TY = ( - 0.0134 \times {a}^{4} - 0.059 \times {a}^{3} + 1.035 \times {a}^{2} - 2.8714 \times a + 5.1253 ) \times b + ( - 0.2858 \times {a}^{4} + 4.6185 \times {a}^{3} - 25.438 \times {a}^{2} + 64.876 \times a - 47.134 )$$

It should be noted that for the mask pattern provided in the embodiments of the present disclosure, when n=3 or n=4, the characteristics of the first surface of the photo spacer prepared by the mask is significantly different from characteristics of the first surface of the photo spacer prepared by HTM in the related art. The outline of the photo spacer prepared in the related art is shown in FIG. 1, a single dent (also called a crater) exists in the middle of the first surface. However, there are a plurality of protrusions on the first surface of the photo spacer prepared by the mask provided by the embodiment of the present disclosure, and a protrusion is provided at the center position of the first surface. For the specific structure of the photo spacer provided in the embodiments of the present disclosure, reference can be made to the specific description of the photo spacer and will not be described here.

It should also be noted here that when n=3 (corresponding to the mask pattern as shown in FIG. 13), in the case that a ratio of the light-transmitting area to the light-shielding area of the mask is 0.2, on the intersection line between the first surface of the photo spacer prepared with the mask pattern and the first cross section, the number of protrusions is 5, the number of dents is 4, the average depth dents is 0.03 μm, and the uniformity (3 δ) of the height PSH of the photo spacer is 0.13 μm.

In the case of n=3, when the width ‘a’ of the light blocking bars and the spacing ‘b’ between the light blocking bars are adjusted, the number of protrusions on the surface and the average depth of dents change.

Exemplarily, when the width ‘a’ of the light blocking bars decreases, the number of protrusions on the intersection line of the first surface of the photo spacer and the first cross section increases, for example, the number of protrusions on the intersection line of the first surface of the photo spacer and the first cross section increases from 3 to 5.

Exemplarily, when the spacing ‘b’ between the light blocking bars increases, the average depth of the dents decreases; for example, when the spacing ‘b’ between the light blocking bars increases from 4.0 μm to 12 μm, the average value of the dent depths (the step difference between the lowest point of the dent and the highest point of the protrusion) decreases from 0.08 μm to 0.02 μm.

when n=4 (corresponding to the mask pattern as shown in FIG. 14), in the case that a ratio of the light-transmitting area to the light-shielding area of the mask is 0.21, on the intersection line between the first surface of the photo spacer prepared with the mask pattern and the first cross section, the number of protrusions is 7, the number of dents is 6, the average depth dents is 0.04 μm, and the uniformity (3 δ) of the height PSH of the photo spacer is 0.15 μm.

It should be noted that for the mask patterns shown in FIG. 13 and FIG. 14, the ratio of the light-transmitting area to the light-shielding area of the mask ranges from 0.1 to 0.3, for example, 0.11, 0.12, 0.13, 0.14, 0.15, 016, 0.17, 0.18, 0.19, 0.2, 0.21, 0.22, 0.23, 0.24, 0.25, 0.28.

For the mask pattern shown in FIG. 15, the ratio of the light-transmitting area to the light-shielding area of the mask ranges from 0.22 to 2.05, for example, 0.23, 0.24, 0.25, 0.28, 0.3, 0.4, 0.5, 0.6, 0.65, 0.7, 0.75, 0.78, 0.8, 0.82, 0.85, 0.9, 1, 1.2, 1.5, 1.6, 1.7, 1.8, 1.9, 2.0.

In addition, based on the previous calculation and analysis, the width ‘a’ of the light blocking bars and the spacing ‘b’ between the light blocking bars are further fitted. According to parameter results of the actual exposure, for the linear relationship between the characteristic values of the photo spacer (PSH, TX, TY) and the spacing ‘b’ between the light blocking bars, the slope and intercept can be expressed by the fourth-order formula of the width ‘a’ of the light blocking bars, which is expressed as:

For the mask pattern as shown in FIG. 15:

$$( 1 ) PSH = ( - 0.0025 \times {a}^{4} + 0.0238 \times {a}^{3} - 0.081 \times {a}^{2} + 0.1199 \times a - 0.1026 ) \times b + ( - 0.0219 \times {a}^{4} + 0.2901 \times {a}^{3} - 1.4549 \times {a}^{2} + 3.2477 \times a + 0.7139 )$$

$$( 2 ) TX = ( - 0.0803 \times {a}^{4} + 0.789 \times {a}^{3} - 3.1103 \times {a}^{2} + 6.5309 \times a - 3.7095 ) \times b + ( 1.46 \times {a}^{4} - 15.167 \times {a}^{3} + 59.915 \times {a}^{2} - 102.6 \times a + 74.222 )$$

$$( 3 ) TY = ( 0.0252 \times {a}^{4} - 0.3229 \times {a}^{3} + 1.3121 \times {a}^{2} - 1.4135 \times a + 1.72 ) \times b + ( - 0.0749 \times {a}^{4} + 1.4349 \times {a}^{3} - 7.1753 \times {a}^{2} + 17.678 \times a - 6.273 ) ;$$

In addition, for the color filter pattern located in the peripheral area BB, it is necessary to set the corresponding mask pattern such that the ratio of the light-transmitting area to the light-shielding area in a range of 0.545 μm±0.15 μm. In this case, the film thickness of the color filter pattern located in the peripheral area BB can be reduced by 0.1 μm˜ 0.5 μm with relative to the film thickness of the color filter pattern located in the display area AA, thereby improving the light leakage and yellowing problems that may occur in the peripheral area BB as mentioned above.

The specific structure of the mask used to prepare the color filter pattern will not be described here, and reference may be made to the pattern of the mask used to prepare the photo spacer mentioned above. In practical applications, depending on the thickness of the color filter pattern, parameters in the pattern of the mask, such as the number ‘n’ of light blocking bars, the width ‘a’ of the light blocking bars, and the spacing ‘b’ between the light blocking bars, can be adjusted to meet the requirements of different products or different areas of the same product for the thickness of the color film pattern.

The above is only specific embodiments of the present disclosure, and the protection scope of the application is not limited thereto. Those skilled in the art can easily conceive of changes or replacements within the scope of the technology disclosed in present disclosure, which should be covered within the scope of protection of the present disclosure. Therefore, the protection scope of the present disclosure should be determined by the protection scope of the claims.

1. A display substrate, comprising:
an underlayer and an organic structure disposed on the underlayer;
wherein the organic structure comprises a first surface arranged away from the underlayer;
in a direction perpendicular to a plane where the underlayer is located, a difference between a maximum distance between the first surface and the underlayer and a minimum distance between the first surface and the underlayer is less than or equal to 0.06 μm.

2. The display substrate according to claim 1, wherein in the direction perpendicular to the plane where the underlayer is located, a distance from a geometric center of the first surface to the underlayer is greater than or equal to an average value of distances from points on the first surface to the underlayer.

3. The display substrate according to claim 1, wherein the organic structure comprises a photo spacer, and a surface of the photo spacer facing away from the underlayer is the first surface.

4. The display substrate according to claim 1, wherein the organic structure comprises color filter patterns, the display substrate comprises a display area and a peripheral area surrounding the display area, a dimension, in the direction perpendicular to the plane where the underlayer is located, of a part of the color filter patterns located in the peripheral area is less than or equal to a dimension, in the direction perpendicular to the plane where the underlayer is located, of a part of the color filter patterns located in the display area;
a surface on a side facing away from the underlayer in an area not overlapping with an adjacent color filter pattern of the color filter pattern located in the peripheral area is the first surface.

5. The display substrate according to claim 3, wherein a plurality of protrusions and a plurality of dents are provided on the first surface, and each of the dents are located between at least two of the protrusions; a geometric center of the first surface is provided with the protrusion.

6. The display substrate according to claim 5, wherein the organic structure comprises a first cross section, the first cross section is a cross section in the direction perpendicular to the plane where the underlayer is located, and an intersection line of the first cross section and the first surface is parallel to a side of the first surface;
a number of the protrusions provided at the intersection line of the first surface and the first cross section is an odd number.

7. The display substrate according to claim 5, wherein the organic structure comprises a first cross section, the first cross section is a cross section in the direction perpendicular to the plane where the underlayer is located, an intersection line of the first cross section and the first surface passes through the geometric center of the first surface;
a number of the protrusions provided at the intersection line of the first surface and the first cross section is an odd number;
wherein an orthographic projection shape of the first surface on the underlayer is a quadrilateral;
the intersection line of the first surface and the first cross section is parallel to a diagonal of the quadrilateral; or
the intersection line of the first surface and the first cross section is parallel to a side of the quadrilateral.

8. (canceled)

9. The display substrate according to claim 5, wherein the first surface comprises a center area and an edge area surrounding the center area, and the geometric center of the first surface is located in the center area;
a maximum distance between a part of the protrusions located in the center area and the underlayer is greater than or equal to a maximum distance between a part of the protrusions located in the edge area and the underlayer.

10. The display substrate according to claim 3, wherein a plurality of the protrusions are provided at an outer contour of the first surface, and a maximum distance between a part of the protrusions located on the outer contour of the first surface and the underlayer is less than or equal to a maximum distance between other protrusions and the underlayer.

11. The display substrate according to claim 3, wherein the first surface comprises a center area and an edge area surrounding the center area, and a geometric center of the first surface is located in the center area;
a curvature radius of a part of protrusions located in the center area is less than or equal to the curvature radius of a part of the protrusions located in the edge area.

12. The display substrate according to claim 7, wherein when the organic structure comprises the photo spacer, the photo spacer comprises a side surface, the side surface being an arc surface, and the intersection line of the side surface and the first cross section is an arc;
wherein a curvature radius of the arc gradually decreases in a direction away from the underlayer.

13. (canceled)

14. The display substrate according to claim 7, wherein when the organic structure comprises the photo spacer, a distance between vertices of two adjacent protrusions in a direction parallel to the plane where the underlayer is located is equal to ½˜⅙ of a dimension of a planar figure of the photo spacer in a preset direction, wherein the preset direction is a direction pointing to one of the two adjacent protrusions from the other one of the two adjacent protrusions.

15. The display substrate according to claim 7, wherein the number of the dents provided at the intersection line of the first surface and the first cross section is an even number, and the number of the protrusions is greater than the number of the dents; or
wherein the number of protrusions provided at the intersection line of the first surface and the first cross section is any one of 3, 5, and 7.

16. (canceled)

17. The display substrate according to claim 1, wherein in the direction perpendicular to the plane where the underlayer is located, a standard deviation of three times the dimension of the organic structure in the direction perpendicular to the plane where the underlayer is located is less than or equal to 0.2 μm.

18. A display panel, comprising the display substrate according to claim 1.

19. A mask for preparing the display substrate according to claim 1, the mask comprises a plurality of first slits, each of the first slits is provided with a plurality of first light blocking bars arranged in the same direction and a plurality of second light blocking bars arranged in the same direction, the first light blocking bar intersects with at least one of the second light blocking bars, and a planar figure of patterns in the first slit is a shape in mirror symmetry;
wherein the number of the first light blocking bars is the same as the number of the second light blocking bars;
wherein the first light blocking bar is arranged to be perpendicular to the second light blocking bar;
wherein a minimum spacing between two adjacent first light blocking bars is equal to a minimum spacing between two adjacent second light blocking bars, and minimum spacing between two adjacent first light blocking bars is greater than a width of the first light blocking bar;
wherein the first light blocking bar and the second light blocking bars have a same structure and same dimensions, any one of the first light blocking bars intersects with all the second light blocking bars, and any one of the second light blocking bars intersects with all the first light blocking bars.

20. (canceled)

21. (canceled)

22. (canceled)

23. (canceled)

24. The mask according to claim 19, wherein the first light blocking bars comprise a first group, a second group and a third group, and the second light blocking bars include a first group, a second group and a third group;
the first group of the first light blocking bars and the second group of the first light blocking bars each comprise two first light blocking bars, the first group of the second light blocking bars and the second group of the second light blocking bars each comprise two second light blocking bars; the third group of the first light blocking bars comprises one of the first light blocking bars, and the third group of the second light blocking bars comprises one of the second light blocking bars;
the first group of the first light blocking bars intersect with the first group of the second light blocking bars to form a first closed ring; the second group of the first light blocking bars intersect with the second group of the second light blocking bars to form a second closed ring; the second closed ring is located inside the first closed ring; the third group of the first light blocking bars intersects with the third group of the second light blocking bars, and the third group of the first light blocking bars and the third group of the second light blocking bars intersect with the first closed ring and the second closed ring respectively, a geometric center of the mask is located at an intersection of the third group of the first light blocking bars and the third group of the second light blocking bars.

25. The mask according to claim 19, wherein the minimum spacing between two adjacent first light blocking bars ranges from 2.5 μm to 14 μm, and the width of the first light blocking bar ranges from 1 μm to 4 μm.

26. A preparation method of a display substrate, wherein the method comprises:
providing an underlayer;
forming a photo spacer material film; and
obtaining a photo spacer by using the mask according to claim 19 to pattern the photo spacer material film; wherein the photo spacer comprises a first surface that is arranged away from the underlayer and is provided with a plurality of protrusions and a plurality of dents, and the dents are located between at least two protrusions; wherein a geometric center of the first surface is provided with the protrusion; in a direction perpendicular to a plane where the underlayer is located, a difference between a maximum distance between the first surface and the underlayer and a minimum distance between the first surface and the underlayer is less than or equal to 0.06 μm.

27. The preparation method according to claim 26, wherein the obtaining a photo spacer by using the mask to pattern the photo spacer material film comprises:
determining a preset height and preset planar dimensions of the photo spacer;
determining two parameters among three parameters of a number of the first light blocking bars in the mask, a width of the first light blocking bars, and a minimum spacing between two adjacent first light blocking bars; wherein the number of the first light blocking bars is the same as the number of the second light blocking bars, the width of the first light blocking bars is the same as the width of the second light blocking bars, and the minimum spacing between two adjacent first light blocking bars is the same as the minimum spacing between two adjacent second light blocking bars;
obtaining a preset relationship between an unknown parameter, among the three parameters of the number of the first light blocking bars, the width of the first light blocking bars, and the minimum spacing between two adjacent first light blocking bars, and dimensional parameters of the photo spacer;
determining the unknown parameter of the mask according to the dimensional parameters of the photo spacer and the preset relationship; and
determining specifications of the mask according to the three parameters of the mask, and then obtaining the photo spacer by using the mask to pattern the photo spacer material film;
wherein the determining two parameters among three parameters of a number of the first light blocking bars in the mask, a width of the first light blocking bars, and a minimum spacing between two adjacent first light blocking bars comprises:
determining the number of the first light blocking bars in the mask and the width of the first light blocking bars;
wherein the obtaining a preset relationship between an unknown parameter, among the three parameters of the number of the first light blocking bars, the width of the first light blocking bars, and the minimum spacing between two adjacent first light blocking bars, and dimensional parameters of the photo spacer comprises:
obtaining the preset relationship between the minimum spacing between two adjacent first light blocking bars and the dimensional parameters of the photo spacer; wherein the dimensional parameters comprise the height and planar dimensions.

28. (canceled)

29. (canceled)

30. (canceled)

31. (canceled)
